(19) United States
(12) Patent Application Publication
(10) Pub. No.: US 2026/0040926 A1
(43) Pub. Date: Feb. 5, 2026

(54) PLACEMENT FLEXIBILITY FOR STANDARD CELLS

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/790,108

(22) Filed: Jul. 31, 2024

(51) Int. Cl. H01L 23/528; H01L 29/06; H01L 29/423; H01L 29/775; H01L 29/78; H01L 29/786

(52) U.S. Cl. CPC H01L 23/5286; H10D 30/43; H10D 30/6211; H10D 30/6735; H10D 30/6757; H10D 62/121

(57) ABSTRACT

A chip includes a first positive supply rail extending in a first direction, a first ground rail extending in the first direction, a second positive supply rail extending in the first direction, and a second ground rail extending in the first direction. The second positive supply rail is aligned with the first ground rail in a second direction perpendicular to the first direction, and the second ground rail is aligned with the first positive supply rail in the second direction.

### FIELD

Aspects of the present disclosure relate generally to chip layout, and more particularly, to placement flexibility for standard cells.

### BACKGROUND

A chip includes many transistors for performing various functions on the chip. The transistors may be implemented using fin field effect transistors (FinFETs), gate-all-around field effect transistors (GAAFETs), and/or other types of transistors. Transistors on the chip may be organized into cells. Each cell may include one or more transistors that are arranged to implement a circuit (e.g., an inverter, a driver, a logic gate, combinational logic, or another type of circuit). The chip may also include frontside metal layers and/or backside metal layers to provide power routing and signal routing for the cells.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first positive supply rail extending in a first direction, a first ground rail extending in the first direction, a second positive supply rail extending in the first direction, wherein the second positive supply rail is aligned with the first ground rail in a second direction perpendicular to the first direction, and a second ground rail extending in the first direction, wherein the second ground rail is aligned with the first positive supply rail in the second direction.

A second aspect relates to a chip. The chip includes a first positive supply rail extending in a first direction, a ground rail extending in the first direction, a second positive supply rail extending in the first direction, wherein the second positive supply rail is aligned with the first positive supply rail in a second direction perpendicular to the first direction, and a third positive supply rail extending in the first direction, wherein the third positive supply rail is aligned with the ground rail in the second direction.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a gate-all-around FET according to certain aspects of the present disclosure.

FIG. 1C shows a perspective view of the transistor implemented with a FinFET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2A shows a top view of an exemplary layout of diffusion regions and gates in a cell according to certain aspects of the present disclosure.

FIG. 2B shows an example in which the orientation of the diffusion regions in FIG. 2A is flipped in the y direction according to certain aspects of the present disclosure.

FIG. 3A shows a top view of an exemplary layout of an n-well and a p-well in the cell according to certain aspects of the present disclosure.

FIG. 3B shows an example in which the orientation of the n-well and the p-well in FIG. 3A is flipped in the y direction according to certain aspects of the present disclosure.

FIG. 4A shows a top view of an exemplary layout of a positive supply rail and a ground rail for routing power to the cell according to certain aspects of the present disclosure.

FIG. 4B shows an example in which the orientation of the positive supply rail and the ground rail in FIG. 4A is flipped in the y direction according to certain aspects of the present disclosure.

FIG. 5A shows an exemplary layout of cells arranged in rows according to certain aspects of the present disclosure.

FIG. 5B shows an exemplary layout of positive supply rails and ground rails arranged along boundaries of the rows of FIG. 5A according to certain aspects of the present disclosure.

FIG. 5C shows an exemplary layout of diffusion regions in the rows of FIG. 5A according to certain aspects of the present disclosure.

FIG. 5D shows an exemplary layout of n-wells and p-wells in the rows of FIG. 5A according to certain aspects of the present disclosure.

FIG. 6 shows a top view of an example of a multi-row cell according to certain aspects of the present disclosure.

FIG. 7A illustrates placement of the multi-row cell of FIG. 6 according to certain aspects of the present disclosure.

FIG. 7B illustrates cell placement restrictions for the multi-row cell of FIG. 6 according to certain aspects of the present disclosure.

FIG. 8 illustrates area inefficiency for a high-performance cell including wide diffusion regions according to certain aspects of the present disclosure.

FIG. 9 shows a top view of a cell that receives power using backside power routing according to certain aspects of the present disclosure.

FIG. 10A shows a top view of an example of a backside positive supply rail and a backside ground rail extending under the cell of FIG. 9 according to certain aspects of the present disclosure.

FIG. 10B shows a cross-sectional view of the cell of FIG. 9 and the backside positive supply rail and the backside ground rail of FIG. 10A according to certain aspects of the present disclosure.

FIG. 11 shows a top view of an exemplary layout of backside power routing according to certain aspects of the present disclosure.

FIG. 12A shows a top view of another example of a backside positive supply rail and a backside ground rail extending under the cell of FIG. 9 according to certain aspects of the present disclosure.

FIG. 12B shows a cross-sectional view of the cell of FIG. 9 and the backside positive supply rail and the backside ground rail of FIG. 12A according to certain aspects of the present disclosure.

FIG. 13 shows a top view of another exemplary layout of backside power routing according to certain aspects of the present disclosure.

FIG. 14A shows an exemplary layout of backside power routing including a power island according to certain aspects of the present disclosure.

FIG. 14B shows an example in which two diffusion regions in FIG. 14A are merged according to certain aspects of the present disclosure.

FIG. 14C shows an example of the layout of FIG. 14A including adjacent cells according to certain aspects of the present disclosure.

FIG. 15 shows another exemplary layout of backside power routing including a power island according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

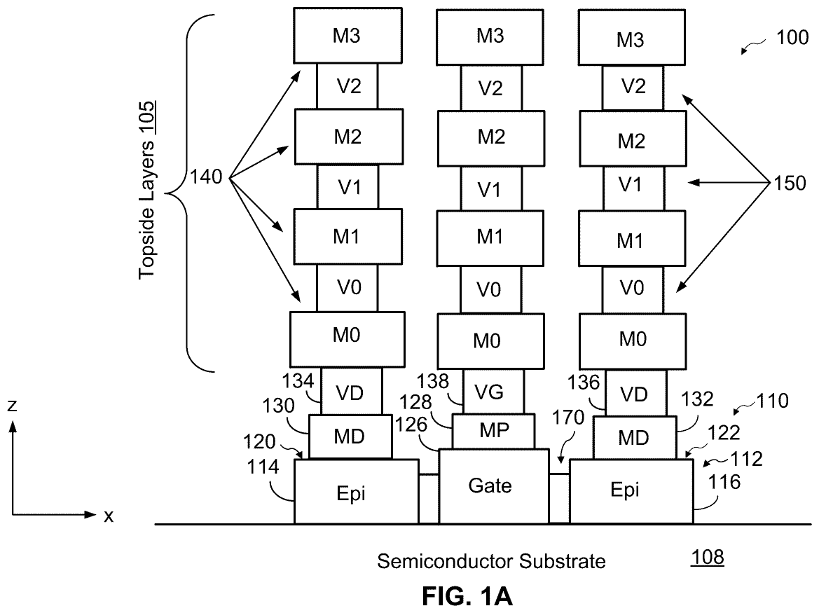

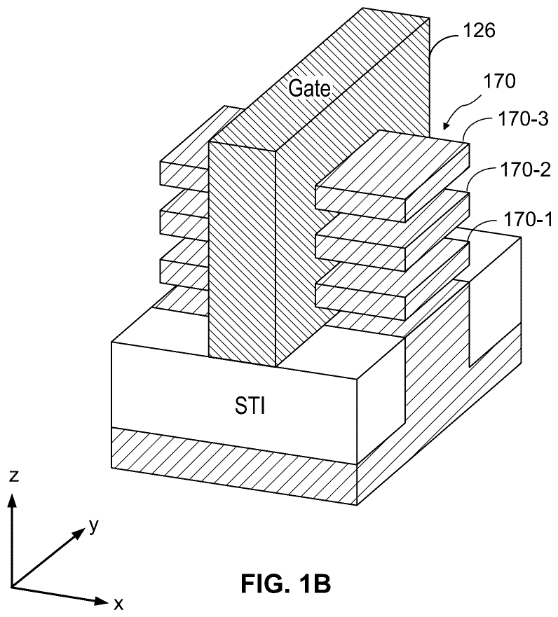

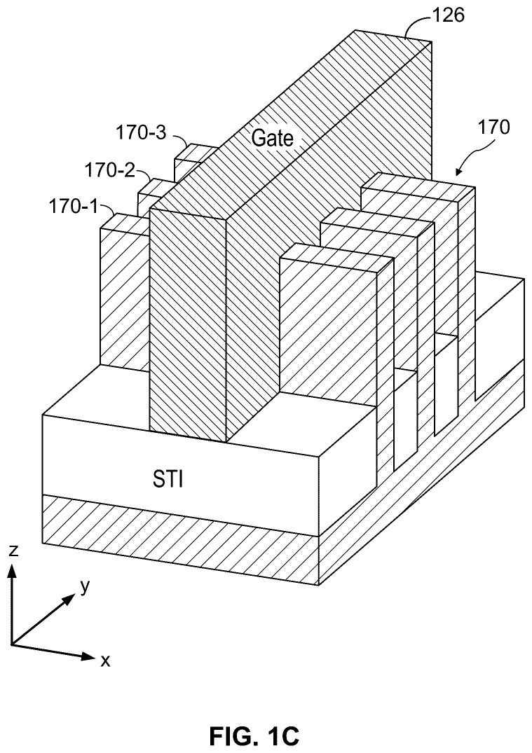

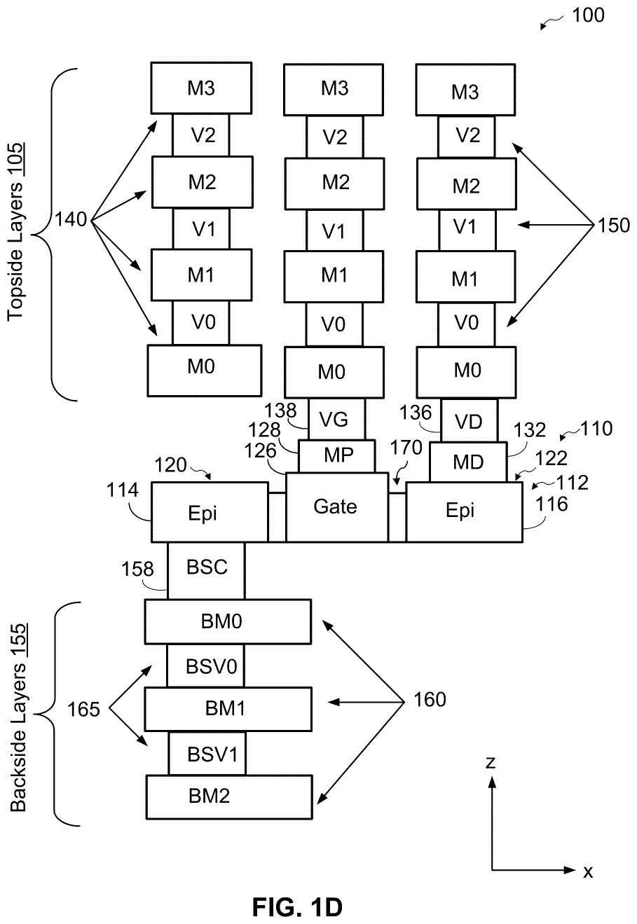

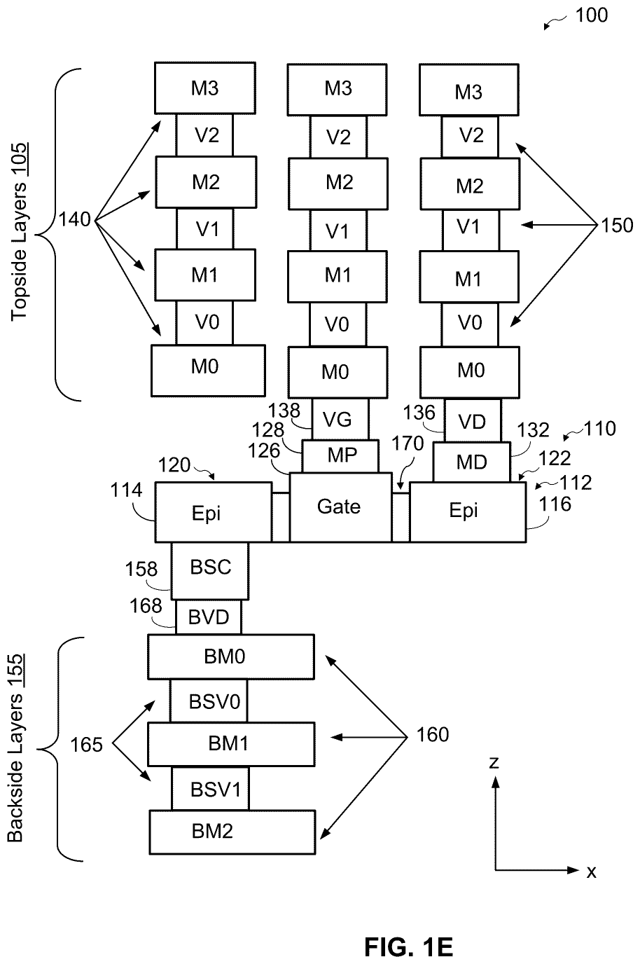

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor.

For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epi layers may be coupled to opposite sides of the one or more channels 170, as discussed further below.

For the example of a gate-all-around FET process, the gate 126 may surround each of the one or more channels 170 (also referred as ribbons) on four sides. In this regard, FIG. 1B shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example. In some implementations, the chip 100 may include shallow trench isolation (STI) to reduce leakage between devices on the chip 100. In other implementations, the STI may be omitted.

For the example of a FinFET process, the gate 126 may surround each of the one or more channels 170 on three sides. In this regard, FIG. 1C shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins. In some implementations, the chip 100 may include shallow trench isolation (STI) to reduce leakage between devices on the chip 100. In other implementations, the STI may be omitted.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a thin spacer (not shown in FIG. 1A) between the gate 126 and the first epi layer 114, and a thin spacer (not shown in FIG. 1A) between the gate 126 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including positive supply rails for distributing power to the transistor 110 and other transistors integrated on the chip 100. A positive supply rail may also be referred to as a power rail, a supply rail, Vdd rail, or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for case of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer MI instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V2. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 138 disposed between the gate contact 128 and metal layer M0, in which the via 138 couples the gate contact 128 (and hence the gate 126) to metal layer M0. For implementations where the gate contact 128 is omitted, the via 138 may be disposed between the gate 126 and metal layer M0 without an intervening gate contact. In this example, the chip 100 also includes a via 134 disposed between the contact 130 and metal layer M0, in which the via 134 couples the contact 130 to metal layer M0. The chip 100 also includes a via 136 disposed between the contact 132 and metal layer M0, in which the via 136 couples the contact 132 to metal layer M0.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP), backside etching, or any combination thereof). Backside layers may then be formed under the transistors on the chip 100.

In this regard, FIG. ID shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include positive supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BMI is referred to as backside metal layer BM2, and so forth. Although three backside metal layers 160 (i.e., BM0 to BM2) are shown in FIG. 1D for case of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including positive supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing. In general, the present disclosure is not limited to a particular allocation of power routing and signal routing between the topside layers 105 and the backside layers 155.

Although one gate 126 is shown in FIGS. 1A to 1E, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Transistors on the chip 100 may be organized into cells. Each cell may include one or more transistors that are arranged to implement a circuit (e.g., an inverter, a driver, a logic gate, combinational logic, a latch, a flip-flop, a bit cell, or another type of circuit). The layout of each cell may be specified (i.e., defined) in a standard cell library, which may be stored in a memory. The standard cell library may specify (i.e., define) the layout of each one of various cells that can be placed (i.e., laid out) on the chip 100 for a particular process. The chip 100 may include multiple instances of a particular cell defined in the standard cell library. The layout of each cell defined in the standard cell library may include the layout of gates, diffusion regions, and contacts in the cell. A cell that is defined in a standard cell library may also be referred to as a standard cell.

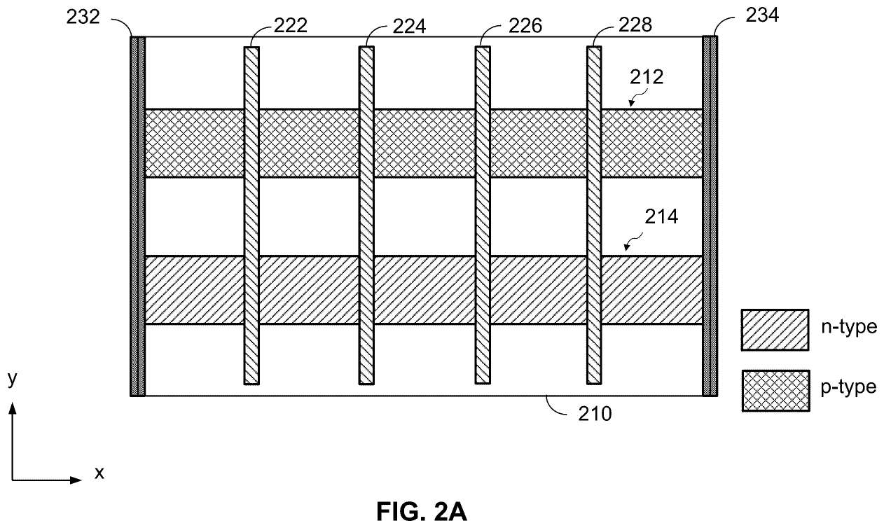

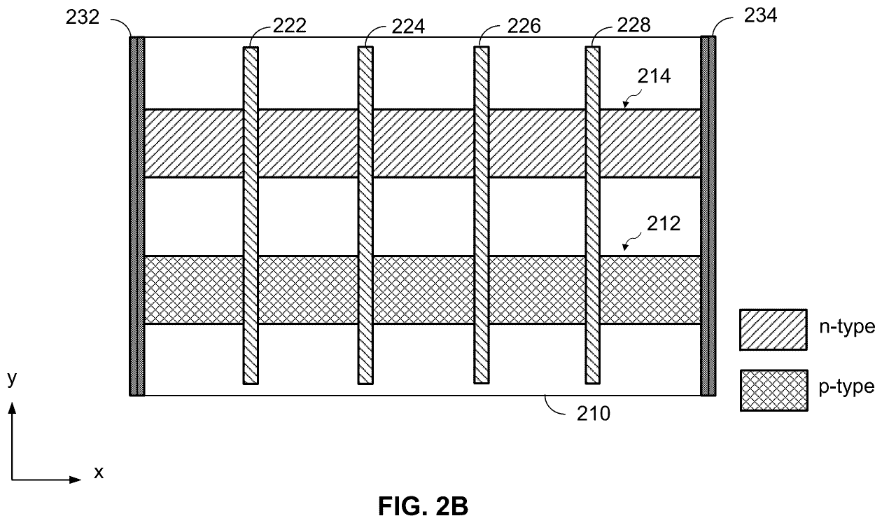

FIG. 2A shows a top view of an exemplary layout of a cell 210 (e.g., a standard cell) according to certain aspects of the present disclosure. In this example, the boundary of the cell 210 is indicated by the rectangular box shown in FIG. 2A.

In this example, the cell 210 include a p-type diffusion region 212 and a n-type diffusion region 214 extending in the x direction. It is to be appreciated that the cell 210 is not limited to two diffusion regions. In general, the cell 210 may include three or more diffusion regions spaced apart in the y direction. For example, in some implementations, the cell 210 may include two p-type diffusion regions and two n-type diffusion regions, as discussed further below.

In this example, the cell 210 also includes gates 222, 224, 226, and 228 extending in the y direction. The gates 222, 224, 226, and 228 may be spaced apart in the x direction by a uniform pitch, as shown in the example in FIG. 2A. Each of the gates 222, 224, 226, and 228 may include a metal (e.g., a high-k metal gate (HKMG)), polysilicon, and/or another gate material. It is to be appreciated that the cell 210 is not limited to the number of gates shown in the example in FIG. 2A, and that the cell 210 may include a smaller number of gates or a larger number of gates (e.g., depending on the complexity of the circuit implemented by the cell 210). It is also to be appreciated that one or more of the gates 222, 224, 226, and 228 may be cut between the p-type diffusion region 212 and the n-type diffusion region 214 (depending on the circuit implemented by the cell 210).

In this example, the p-type diffusion region 212 may include one or more channels (e.g., the one or more channels 170) passing through the gates 222, 224, 226, and 228 and epi layers (e.g., the epi layers 114 and 116) between the gates 222, 224, 226, and 228. The p-type diffusion region 212 and the gates 222, 224, 226, and 228 may form one or more p-type field effect transistors (PFETs) in the cell 210. The n-type diffusion region 214 may include one or more channels (e.g., the one or more channels 170) passing through the gates 222, 224, 226, and 228 and epi layers (e.g., the epi layers 114 and 116) between the gates 222, 224, 226, and 228. The n-type diffusion region 214 and the gates 222, 224, 226, and 228 may form one or more n-type field effect transistors (NFETs) in the cell 210.

FIG. 2A also shows an example of a first diffusion break 232 on the left boundary of the cell 210, and a second diffusion break 234 on the right boundary of the cell 210. The diffusion breaks 232 and 234 may be used to isolate the diffusion regions 212 and 214 from diffusion regions of adjacent cells (not shown in FIG. 2A). Each of the diffusion breaks 232 and 234 may include a single diffusion break, a double diffusion break, or another type of diffusion break.

FIG. 2B shows an example of the cell 210 in which the orientation of the p-type diffusion region 212 and the n-type diffusion region 214 is flipped in the y direction with respect to the orientation of the p-type diffusion region 212 and the n-type diffusion region 214 in FIG. 2A.

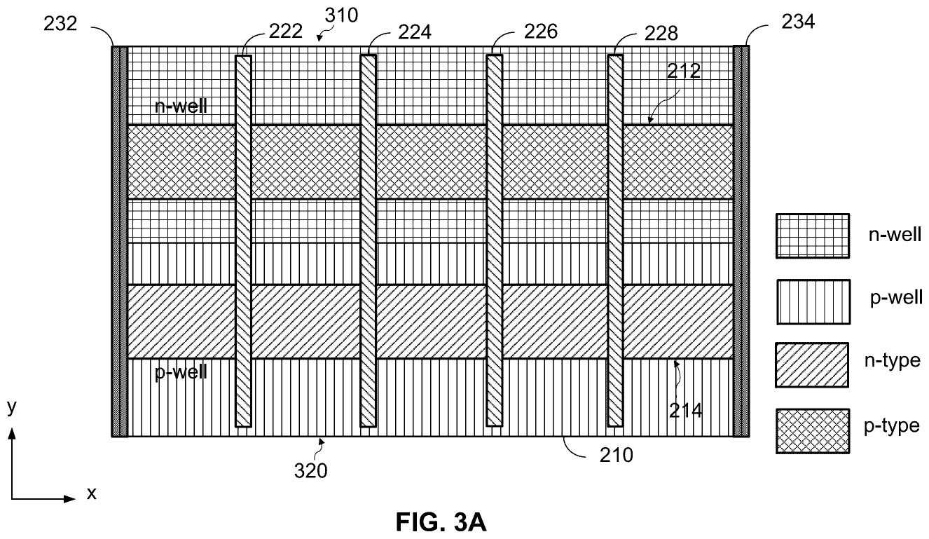

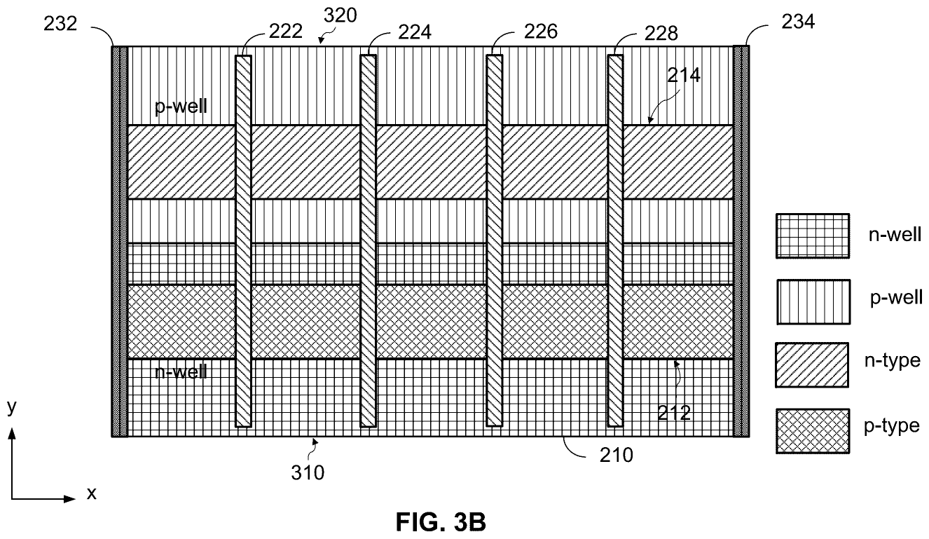

In certain aspects, the cell 210 is formed on the semiconductor substrate 108 (shown in FIG. 1A). In this regard, FIG. 3A shows an example in which an n-well 310 is formed in the substrate 108 to provide a substrate region for the PFET(s) and a p-well 320 is formed in the substrate 108 to provide a substrate region for the NFET(s). In the example in FIG. 3A, the n-well 310 extends in the x direction under the p-type diffusion region 212, and the p-well 320 extends in the x direction under the n-type diffusion region 214. In this example, the n-well 310 may be coupled to a supply voltage by an n-well tap cell (not shown) and the p-well 320 may be coupled to ground potential by a p-well tap cell (not shown). In certain aspects, n-well tap cells and p-well tap cells may be placed periodically on the chip 100 to tie n-wells to the supply voltage and tie p-wells to ground potential to prevent latch up. As discussed further below, the n-well 310 and the p-well 320 may be omitted in some implementations (e.g., implementations where all or substantially all of the substrate 108 is removed to form the backside layers 155 shown in FIGS. ID and 1E). For example, the n-well 310 and the p-well 320 may be omitted for a substrate-free implementation with a backside power distribution network (BSPDN).

FIG. 3B shows an example in which the orientation of the n-well 310 and the p-well 320 is flipped in the y direction with respect to the orientation of the n-well 310 and the p-well 320 in FIG. 3A. In this example, the orientation of the p-type diffusion region 212 and the n-type diffusion region 214 is also flipped in the y direction with respect to the orientation of the p-type diffusion region 212 and the n-type diffusion region 214 in FIG. 3A.

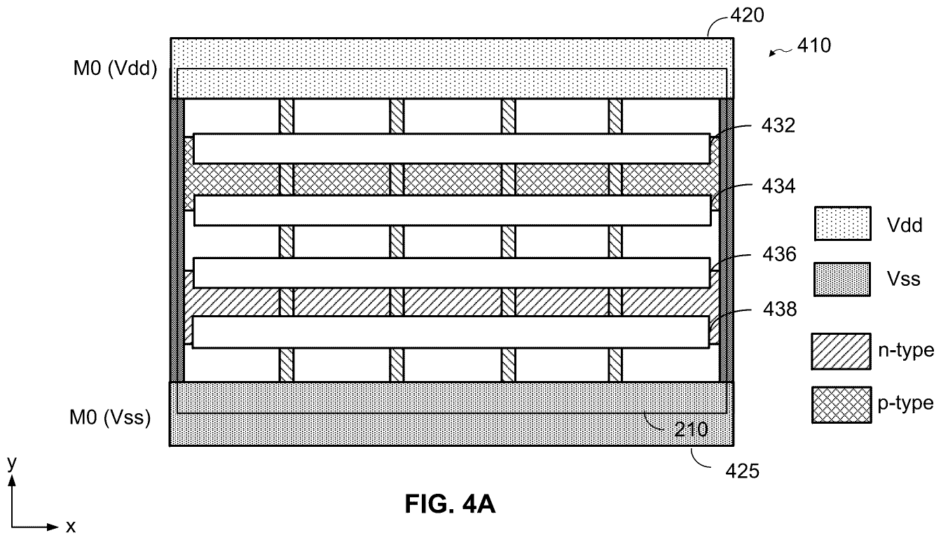

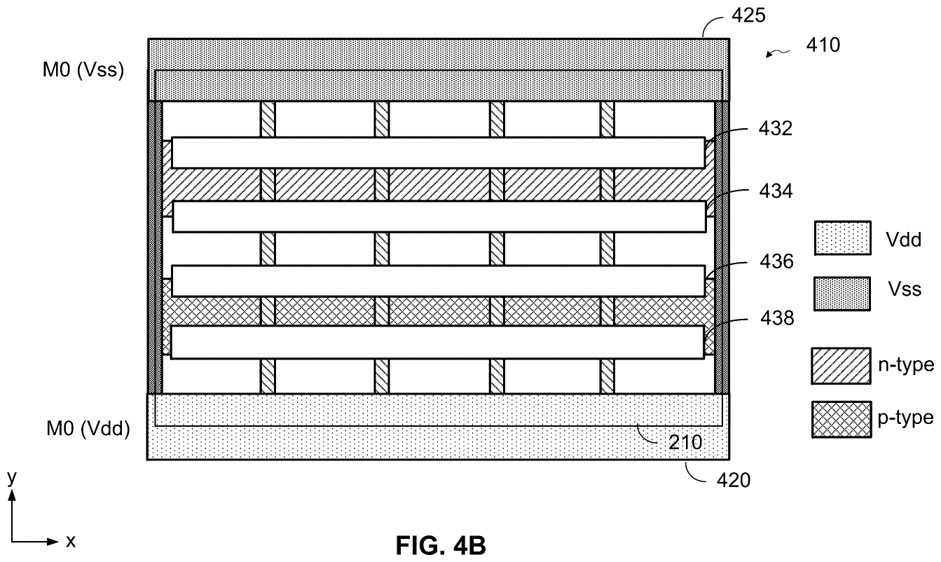

FIG. 4A shows a top view of an exemplary layout 410 for power routing and signal routing in metal layer MO over the cell 210. FIG. 4A shows an example of frontside power routing in which power is routed to the cell 210 from the frontside (e.g., using a power distribution network formed in the topside metal layers 105 in FIG. 1A).

In the example in FIG. 4A, the layout 410 includes a positive supply rail 420 and a ground rail 425 that provide frontside power routing for the cell 210. Each of the rails 420 and 425 is elongated and extends in the x direction. Each of the rails 420 and 425 are formed in metal layer MO (e.g., using lithography and etching processes). Although the positive supply rail 420 and the ground rail 425 are formed in the same metal layer, the positive supply rail 420 and the ground rail 425 are shown with different shading in FIG. 4A to visually distinguish the positive supply rail 420 and the ground rail 425. As discussed above, a positive supply rail may also be referred to as a Vdd rail. A ground rail may also be referred to as a negative supply rail, a Vdd rail, or another term.

In the example shown in FIG. 4A, the positive supply rail 420 overlaps the top boundary (i.e., edge) of the cell 210 in the x and y directions, and the ground rail 425 overlaps the bottom boundary (i.e., edge) of the cell 210 in the x and y directions. The p-type diffusion region 212 may be coupled to the positive supply rail 420 through one or more contacts (e.g., MD contact in FIG. 1A) and one or more vias (e.g., VD via in FIG. 1A). The n-type diffusion region 214 may be coupled to the ground rail 425 through one or more contacts (e.g., MD contact in FIG. 1A) and one or more vias (e.g., VD via in FIG. 1A).

As discussed further below, the cell 210 may share the positive supply rail 420 and the ground rail 425 with one or more other cells on the chip 100.

In the example shown in FIG. 4A, the layout 410 also includes tracks 432, 434, 436, and 438 in metal layer MO located between the positive supply rail 420 and the ground rail 425 in the y direction. The tracks 432, 434, 436, and 438 are used to provide signal routing for the cell 210. Each of the tracks 432, 434, 436, and 438 is elongated and extends in the x direction. The tracks 432, 434, 436, and 438 are spaced apart in the y direction (e.g., by a uniform pitch). A track may also be referred to as a wire or another term. Each of the tracks 432, 434, 436, and 438 may be coupled to one or more of the gates (e.g., through one or more MP contacts and one or more VG vias in FIG. 1A) and/or coupled to one or more of the diffusion regions 212 and 214 (e.g., through one or more MD contacts and one or more VD vias in FIG. 1A). The cell 210 may utilize all four tracks 432, 434, 436, and 438 for signal routing or less than all four tracks 432, 434, 436, and 438 for signal routing depending, for example, on the number of inputs and outputs of the circuit implemented by the cell 210.

For the example where the cell 210 includes the n-well 310 (shown in FIG. 3A), the n-well 310 may be coupled to the positive supply rail 420 through an n-well tap (not shown). The n-well tap may be located in another cell (not shown) in which the n-well 310 extends in the x direction to the other cell. For the example where the cell 210 includes the p-well 320 (shown in FIG. 3A), the p-well 320 may be coupled to the ground rail 425 through a p-well tap (not shown). The p-well tap may be located in another cell (not shown) in which the p-well 320 extends in the x direction to the other cell.

FIG. 4B shows an example in which the orientation of the positive supply rail 420 and the ground rail 425 is flipped in the y direction with respect to the orientation of the positive supply rail 420 and the ground rail 425 in FIG. 4A. In this example, the ground rail 425 overlaps the top boundary of the cell 210 in the x and y directions, and the positive supply rail 420 overlaps the bottom boundary of the cell 210 in the x and y directions. Also, in the example in FIG. 4B, the orientation of the p-type diffusion region 212 and the n-type diffusion region 214 is flipped in the y direction with respect to the orientation of the p-type diffusion region 212 and the n-type diffusion region 214 in FIG. 4A.

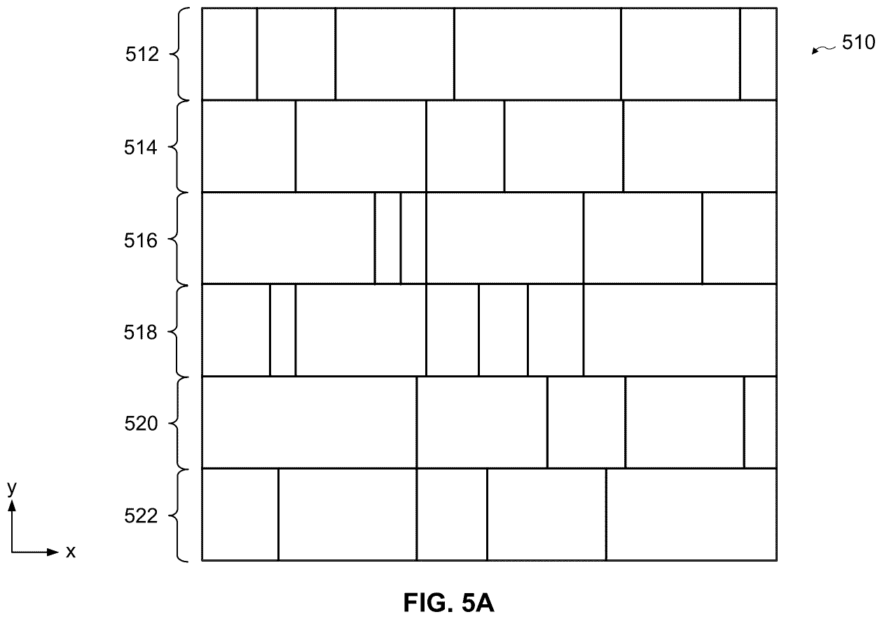

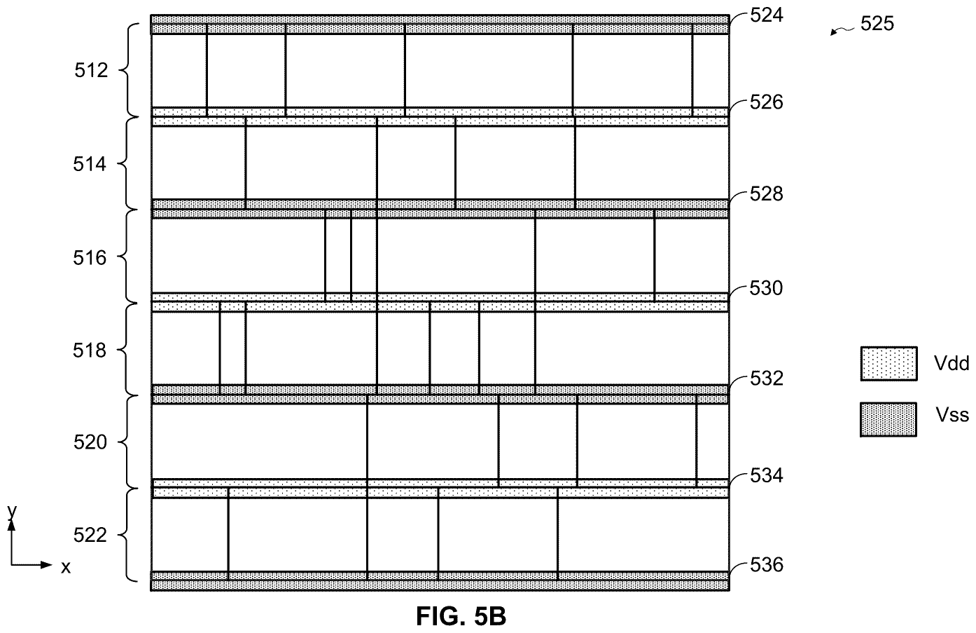

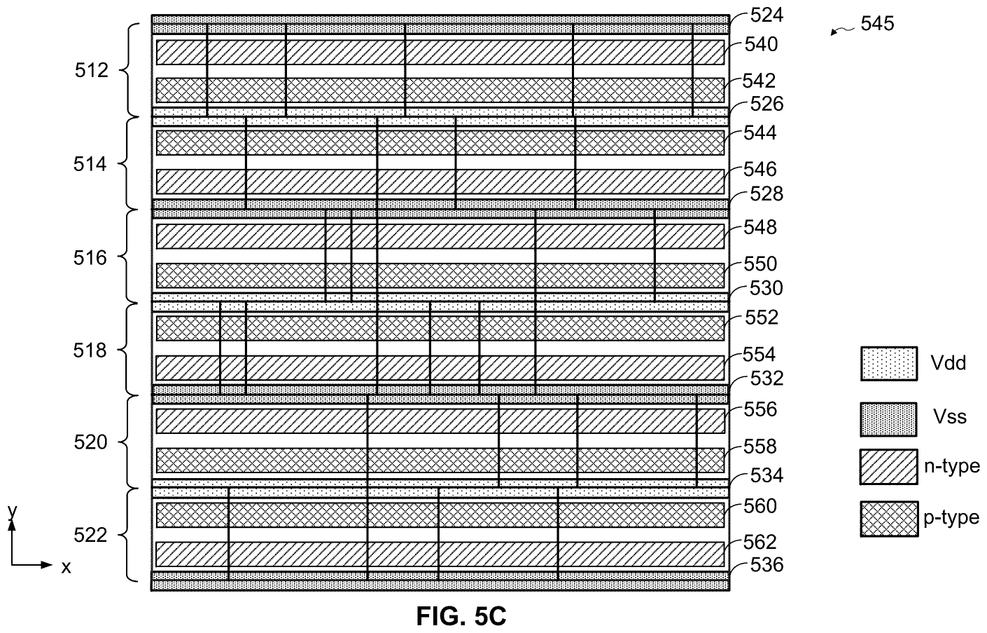

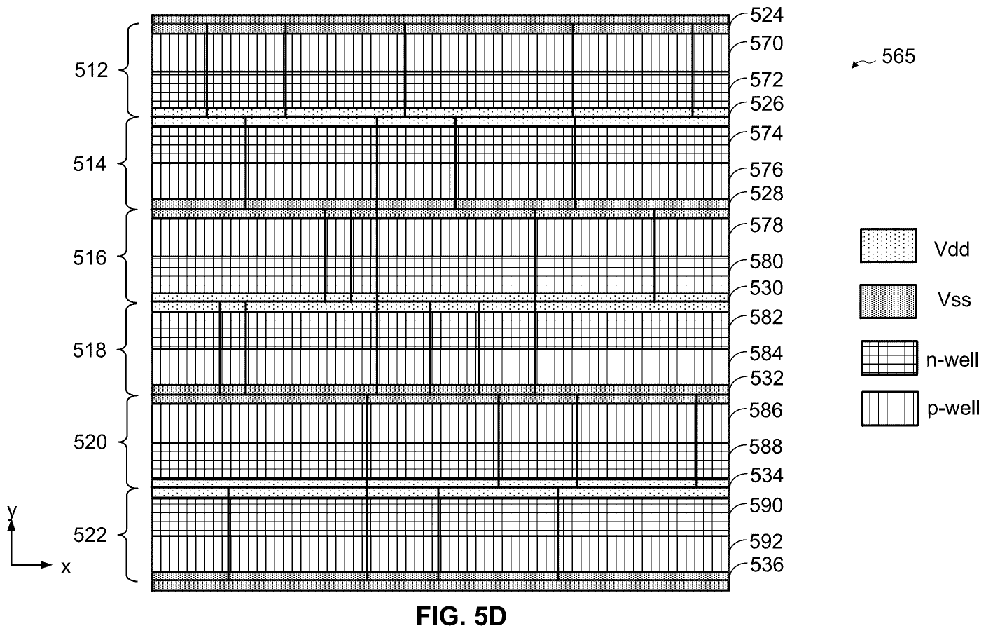

In certain aspects, standard cells may be arranged (i.e., laid out) in rows on the chip 100. In this regard, FIG. 5A shows a top view of an exemplary layout 510 of standard cells arranged in rows 512, 514, 516, 518, 520, and 522 extending in the x direction. In FIG. 5A, each cell is shown as a rectangular box delineating the boundary of the cell.

In this example, the cells in each of the rows 512, 514, 516, 518, 520, and 522 have the same height in the y direction. The cells in each of the rows 512, 514, 516, 518, 520, and 522 may have the same width in the x direction or varying widths in the x direction (e.g., based on the number of gates in each cell). For example, a cell with a larger number of gates may be wider in the x direction than a cell with a smaller number of gates.

FIG. 5B shows an example layout 525 of positive supply rails 526, 530, and 534 and ground rails 524, 528, 532, and 536 for distributing power to the cells in the rows 512, 514, 516, 518, 520, and 522. In this example, each of the positive supply rails 526, 530, and 534 extends in the x direction and each of the ground rails 524, 528, 532, and 536 extends in the x direction. Also, in this example, the layout 525 alternates between the positive supply rails 526, 530, and 534 and the ground rails 524, 528, 532, and 536 in the y direction. As discussed further below, the alternating arrangement of the positive supply rails 526, 530, and 534 and the ground rails 524, 528, 532, and 536 in the y direction allows each of the positive supply rails 526, 530, and 534 to be shared by cells in adjacent rows and each of the ground rails 524, 528, 532, and 536 to be shared by cells in adjacent rows.

In the example shown in FIG. 5B, each of the rows 512, 514, 516, 518, 520, and 522 is located between one of the positive supply rails 526, 530, and 534 and one of the ground rails 524, 528, 532, and 536. For example, the row 512 is located between the positive supply rail 526 and the ground rail 524. In this example, power is distributed to the cells in the row 512 using the positive supply rail 526 and the ground rail 524.

FIG. 5C shows an example layout 545 of n-type diffusion regions 540, 546, 548, 554, 556, and 562 and p-type diffusion regions 542, 544, 550, 552, 558, and 560 according to certain aspects. Each of the n-type diffusion regions 540, 546, 548, 554, 556, and 562 and each of the p-type diffusion regions 542, 544, 550, 552, 558, and 560 extends in the x direction. In this example, each of the rows 512, 514, 516, 518, 520, and 522 includes a respective one of the n-type diffusion regions 540, 546, 548, 554, 556, and 562 and a respective one of the p-type diffusion regions 542, 544, 550, 552, 558, and 560. The layout 545 may also include diffusion breaks (not shown) on the boundaries of adjacent cells in the same row.

In the example in FIG. 5C, the orientation of the n-type diffusion region and the p-type diffusion region in each row is flipped in the y direction with respect to the orientation of n-type diffusion region and the p-type diffusion region in an adjacent row. For example, in FIG. 5C, the orientation of the n-type diffusion region 540 and the p-type diffusion region 542 in the row 512 is flipped in the y direction with respect to the orientation of the n-type diffusion region 546 and the p-type diffusion region 544 in the adjacent row 514. This places both the p-type diffusion region 542 in the row 512 and the p-type diffusion region 544 in the adjacent row 514 next to the positive supply rail 526 allowing the positive supply rail 526 to be shared by the cells in the rows 512 and 514.

Also, in FIG. 5C, the orientation of the n-type diffusion region 546 and the p-type diffusion region 544 in the row 514 is flipped in the y direction with respect to the orientation of the n-type diffusion region 548 and the p-type diffusion region 550 in the adjacent row 516. This places both the n-type diffusion region 546 in the row 514 and the n-type diffusion region 548 in the adjacent row 516 next to the ground rail 528 allowing the ground rail 528 to be shared by the cells in the rows 514 and 516.

FIG. 5D shows an example layout 565 of n-wells 572, 574, 580, 582, 588, and 590 and p-wells 570, 576, 578, 584, 586, and 592 according to certain aspects. Note that the n-type diffusion regions 540, 546, 548, 554, 556, and 562 and the p-type diffusion regions 542, 544, 550, 552, 558, and 560 are not shown in FIG. 5D in order to better show the n-wells 572, 574, 580, 582, 588, and 590 and the p-wells 570, 576, 578, 584, 586, and 592.

Each of the n-wells 572, 574, 580, 582, 588, and 590 and each of the p-wells 570, 576, 578, 584, 586, and 592 extends in the x direction. In this example, each of the rows 512, 514, 516, 518, 520, and 522 includes a respective one of the n-wells 572, 574, 580, 582, 588, and 590 and a respective one of the p-wells 570, 576, 578, 584, 586, and 592. In each of the rows 512, 514, 516, 518, 520, and 522, the respective one of the n-wells 572, 574, 580, 582, 588, and 590 is located under the respective one of the p-type diffusion regions 542, 544, 550, 552, 558, and 560 (shown in FIG. 5C). Also, in each of the rows 512, 514, 516, 518, 520, and 522, the respective one of the p-wells 570, 576, 578, 584, 586, and 592 is located under the respective one of the n-type diffusion regions 540, 546, 548, 554, 556, and 562 (shown in FIG. 5C).

In the examples shown in FIGS. 5A to 5D, the cell 210 (which has a height of one row) may be freely placed in any one of the rows 512, 514, 516, 518, 520, and 522. This is because, the orientation of the p-type diffusion region 212 and the n-type diffusion region 214 in the cell 210 may be selected based on the row in which the cell is placed. For example, to place the cell 210 in the row 514, the exemplary orientation of the p-type diffusion region 212 and the n-type diffusion region 214 shown in FIG. 2A may be used. To place the cell 210 in the row 516, the exemplary orientation of the p-type diffusion region 212 and the n-type diffusion region 214 shown in FIG. 2B may be used. Thus, the cell 210 may use either one of the orientations of the p-type diffusion region 212 and the n-type diffusion region 214 shown in FIGS. 2A and 2B depending on the row in which the cell 210 is placed.

However, the layout 525 of the positive supply rails 526, 530, and 534 and the ground rails 524, 528, 532, and 536 shown in FIG. 5B and the layout 565 of the n-wells 572, 574, 580, 582, 588, and 590 and the p-wells 570, 576, 578, 584, 586, and 592 shown in FIG. 5C place restrictions on the placement of multi-row cells. A multi-row cell is a cell having a height in the y direction that is equal to the height of two or more rows in the y direction. The restrictions on the placement of multi-row cells leads to multi-row cell placement inefficiency, as discussed further below.

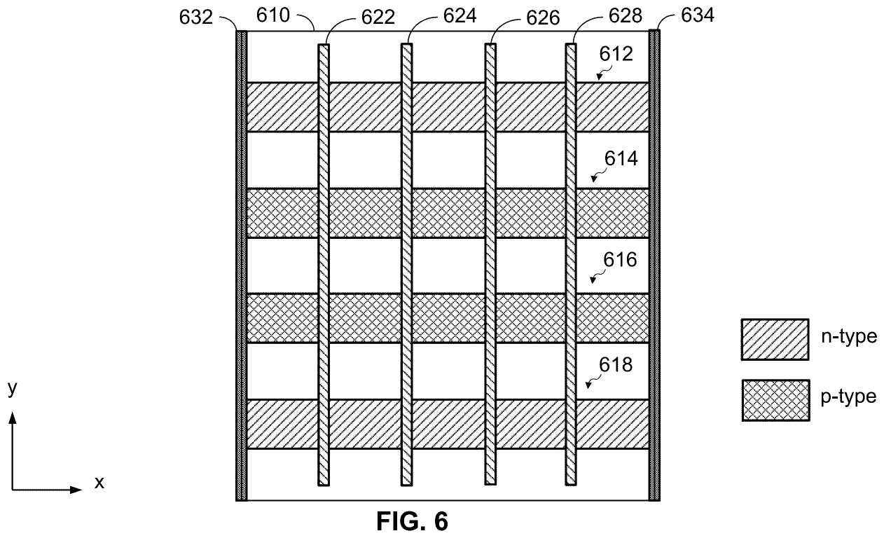

FIG. 6 shows a top view of an exemplary layout of a multi-row cell 610 according to certain aspects of the present disclosure. In this example, the multi-row cell 610 has a height of two rows in the y direction.

In the example in FIG. 6, the cell 610 includes a first n-type diffusion region 612, a second n-type diffusion region 618, a first p-type diffusion region 614, and a second p-type diffusion region 616. Each of the diffusion regions 612, 614, 616, and 618 extends in the x direction, and the diffusion regions 612, 614, 616, and 618 are spaced apart in the y direction. In some implementations, the first p-type diffusion region 614 and the second p-type diffusion region 616 may be merged into one wider p-type diffusion to have better performance. Each of the diffusion regions 612, 614, 616, and 618 may include one or more epi layers (e.g., one or more instances of the epi layers 114 and 116) and one or more channels (e.g., one or more instances of the one or more channels 170).

In this example, the cell 610 may also include gates 622, 624, 626, and 628. Each of the gates 622, 624, 626, and 628 extends in the y direction, and the gates 622, 624, 626, and 628 are spaced apart in the x direction. It is to be appreciated that the cell 610 is not limited to the number of gates shown in the example in FIG. 6, and that the cell 610 may include a smaller number of gates or a larger number of gates. It is also to be appreciated that one or more of the gates 622, 624, 626, and 628 may be cut at one or more locations between the diffusion regions. FIG. 6 also shows an example of a first diffusion break 632 on the left boundary of the cell 610, and a second diffusion break 634 on the right boundary of the cell 610.

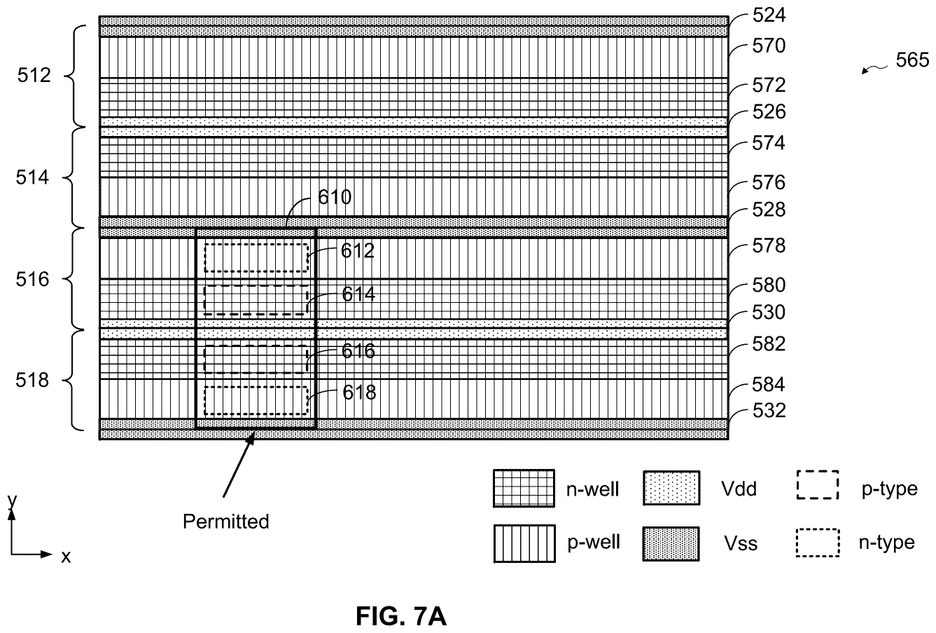

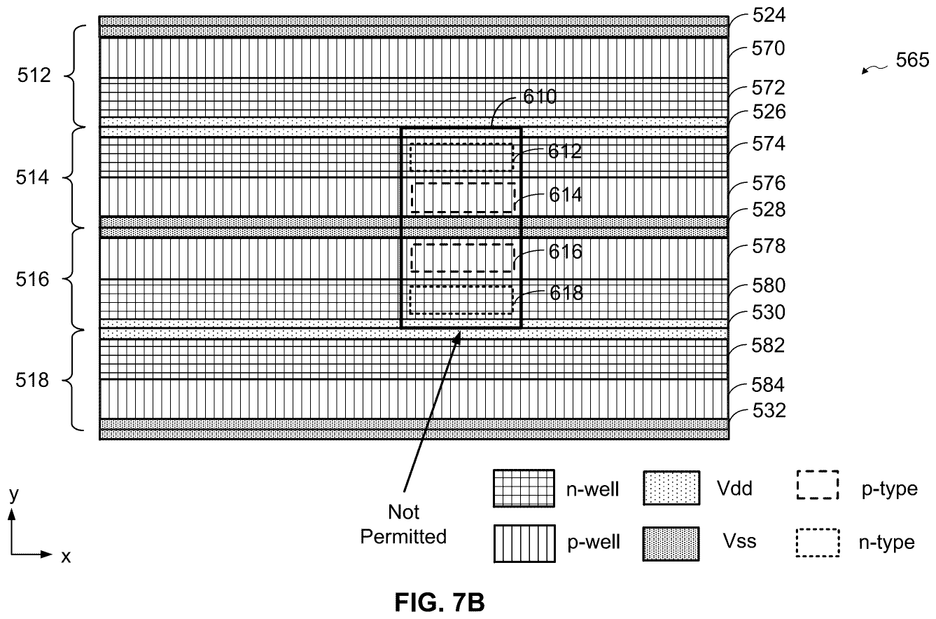

FIG. 7A shows an example of a placement of the multi-row cell 610 that is permitted by the layouts shown in FIGS. 5A to 5D according to certain aspects. In FIG. 7A, the n-type diffusion regions 612 and 618 of the cell 610 are shown in dotted line, and the p-type diffusion regions 614 and 616 are shown in dashed line. Note that the individual cells shown in FIGS. 5A to 5D are not shown in FIG. 7A in order to illustrate placement options for the cell 610.

FIG. 7A shows an example of a placement of the cell 610 that is permitted in which the cell 610 extends across the rows 516 and 518. This placement is permitted because the p-wells 578 and 584 are located under the n-type diffusion regions 612 and 618 of the cell 610, and the n-wells 580 and 582 are located under the p-type diffusion regions 614 and 616 of the cell 610, as shown in FIG. 7A.

FIG. 7B shows an example of a placement of the cell 610 that is not permitted in which the cell 610 extends across the row 514 and 516. This placement is not permitted because the n-wells 574 and 580 are located under the n-type diffusion regions 612 and 618 of the cell 610 (which is not allowed), and the p-wells 576 and 578 are located under the p-type diffusion regions 614 and 616 of the cell 610 (which is not allowed). In addition, the first n-type diffusion region 612 is located next to the positive supply rail 526 (which is not allowed), the second n-type diffusion region 618 is located next to the positive supply rail 530 (which is not allowed), and the p-type diffusion regions 614 and 616 are located next to the ground rail 528 (which is not allowed).

In addition, the layout 525 of the positive supply rails 526, 530, and 534 and the ground rails 524, 528, 532, and 536 shown in FIG. 5B and the layout 565 of the n-wells 572, 574, 580, 582, 588, and 590 and the p-wells 570, 576, 578, 584, 586, and 592 shown in FIG. 5C also lead to area inefficiency for symmetric wide high-performance (HP) cells. An HP cell is a cell including diffusion regions that have wider widths in the y direction than diffusion regions in a single row cell (e.g., the cell 210). The wider diffusion regions provide higher performance (e.g., larger drive strength).

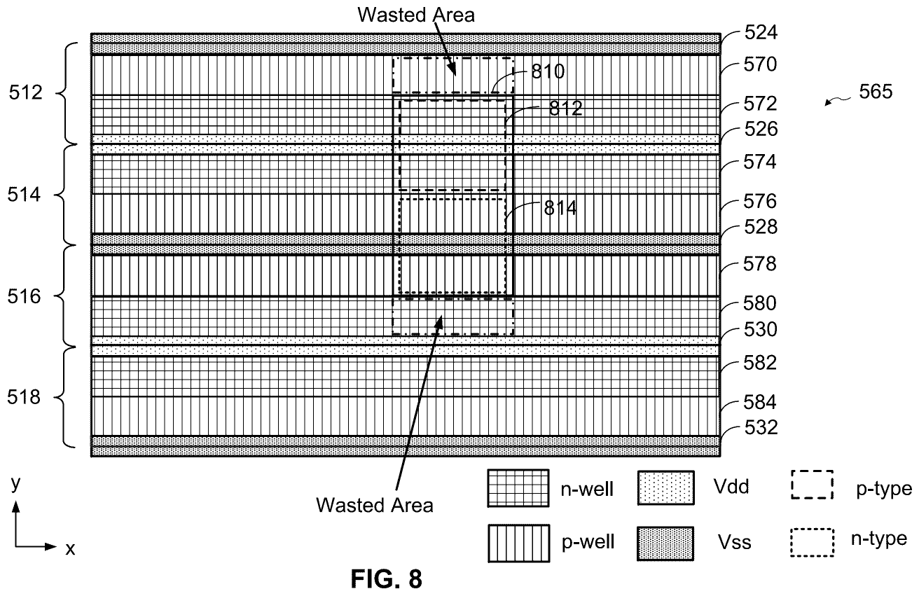

The area inefficiency for an exemplary HP cell 810 is shown in FIG. 8. In this example, the HP cell 810 has a height of two rows in the y direction. The HP cell 810 includes a wide p-type diffusion region 812 (shown in dashed line) and a wide n-type diffusion region 814 (shown in dotted line). In the example in FIG. 8, the wide p-type diffusion region 812 extends over the n-wells 572 and 574, and the wide n-type diffusion region 814 extends over the p-wells 576 and 578. Each of the diffusion regions 812 and 814 may include one or more epi layers (e.g., one or more instances of the epi layers 114 and 116) and one or more channels (e.g., one or more instances of the one or more channels 170).

In this example, the HP cell 810 extends across the row 514 in the y direction. The HP cell 810 also extends partially across the row 512 in the y direction in order to place the n-well 572 in the row 512 under the wide p-type diffusion region 812. Because the HP cell 810 extends only partially across the row 512, an area of the row 512 above the cell 810 in the y direction is wasted. The wasted arca in the row 512 is indicated by a dash-dotted line.

The HP cell 810 also extends partially across the row 516 in the y direction in order to place the p-well 578 in the row 516 under the wide n-type diffusion region 814. Because the HP cell 810 extends only partially across the row 516, an area of the row 516 below the cell 810 in the y direction is wasted. The wasted arca in the row 516 is indicated by a dash-dotted line.

Thus, in this example, the cell 810 extends across the row 514 and extends partially across the rows 512 and 516. As a result, an area extending across three rows is needed for placement of the cell 810, which leads to the wasted areas shown in FIG. 8. The wasted areas reduce area efficiency.

The cell placement restrictions due to the layout 565 of the n-wells 572, 574, 580, 582, 588, and 590 and the p-wells 570, 576, 578, 584, 586, and 592 shown in FIG. 5C may be eliminated using backside power routing for the cells. This is because all or substantially all of the substrate 108 is removed for backside processing which may eliminate the need for n-wells and p-wells, as discussed further below.

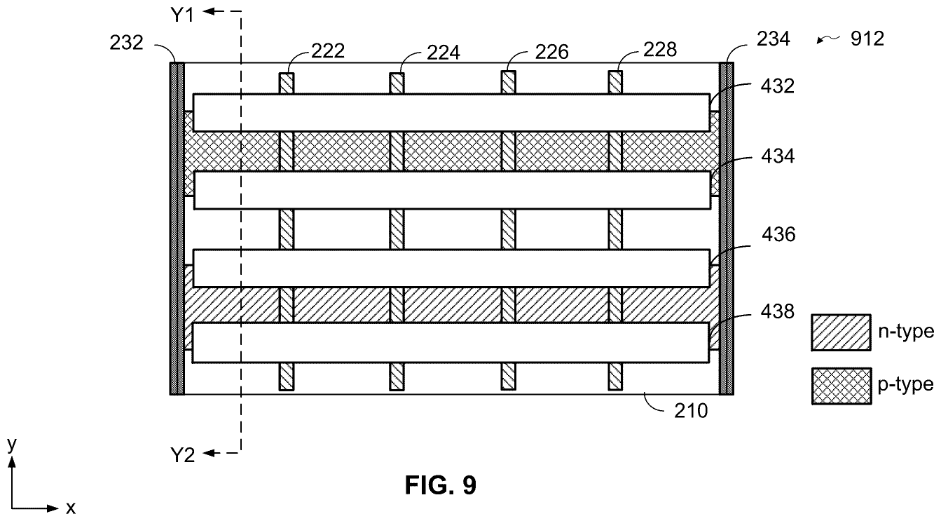

FIG. 9 shows a top view of the cell 210 and the tracks 432, 434, 436, and 438 in metal layer M0. As discussed above, the tracks 432, 434, 436, and 438 provide signal routing for the cell 210. In this example, power is routed to the cell 210 from the backside using a backside power distribution network (BSPDN). Since power is routed from the backside in this example, the positive supply rail 420 and the ground rail 425 in metal layer MO shown in FIGS. 4A and 4B are omitted. Moving the power routing to the backside reduces signal routing congestion by freeing up more space in the topside layers 105 for signal routing.

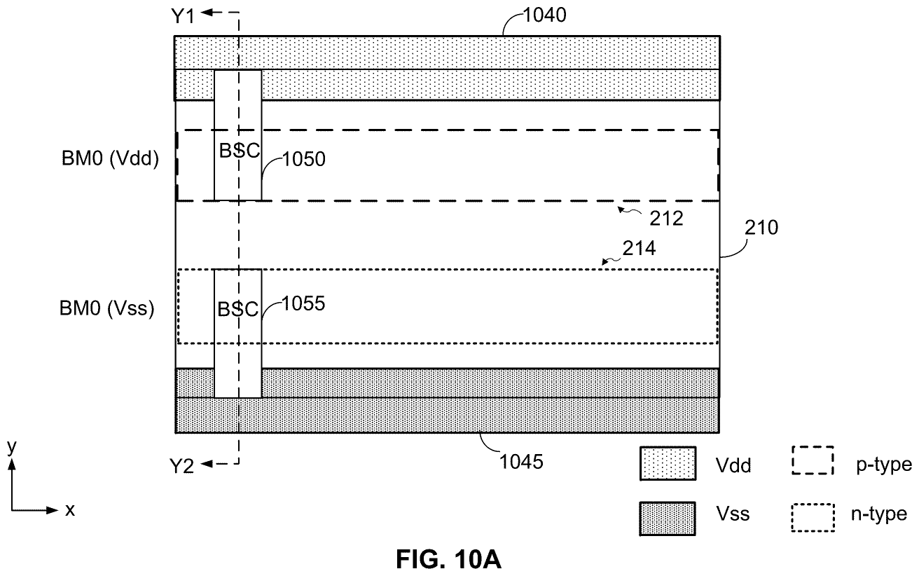

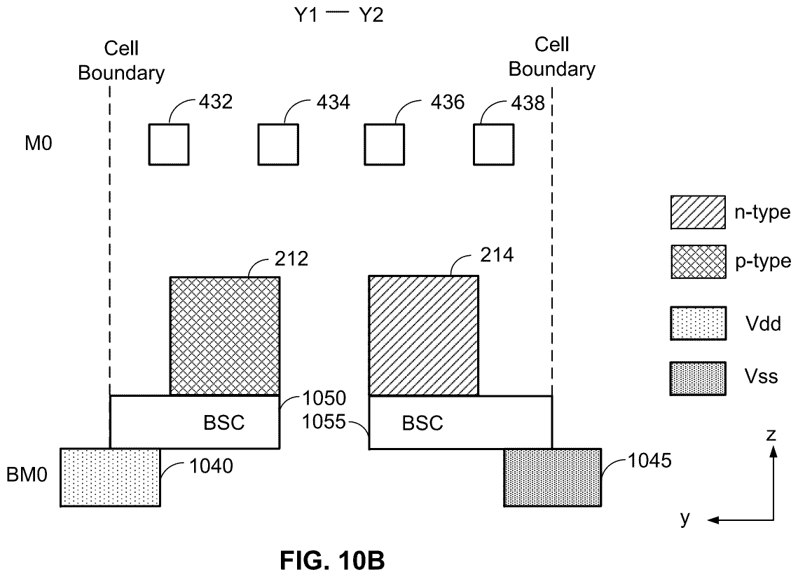

FIG. 10A shows a top view of an example of backside power routing for the cell 210 according to certain aspects. In this example, the backside power routing includes a backside positive supply rail 1040 and a backside ground rail 1045 in backside metal layer BM0. In FIG. 10A, the p-type diffusion region 212 is shown in dashed line, and the n-type diffusion region 214 is shown in dotted line. The gates 222, 224, 226, and 228 and the tracks 432, 434, 436, and 438 are not shown in FIG. 10A.

In this example, the backside positive supply rail 1040 extends in the x direction and overlaps the top boundary of the cell 210 in the x and y directions, which allows the backside positive supply rail 1040 to be shared with an adjacent cell (not shown) located in an adjacent row. The backside ground rail 1045 extends in the x direction and overlaps the bottom boundary of the cell 210 in the x and y directions, which allows the backside ground rail 1045 to be shared with an adjacent cell (not shown) located in an adjacent row. The backside positive supply rail 1040 receives the supply voltage Vdd from the backside distribution network formed in the backside layers 155 (shown in FIGS. ID and 1E)

FIG. 10A shows a cross-sectional view of the tracks 432, 434, 436, and 438, the diffusion regions 212 and 214, the backside positive supply rail 1040, and the backside ground rail 1045 taken along line Y1-Y2 in FIGS. 9 and 10A. In this example, the p-type diffusion region 212 is coupled to the backside positive supply rail 1040 through a first backside contact 1050. The first backside contact 1050 is coupled to a bottom surface of the p-type diffusion region 212 and extends in the y direction to the backside positive supply rail 1040. The n-type diffusion region 214 is coupled to the backside ground rail 1045 through a second backside contact 1055. The second backside contact 1055 is coupled to a bottom surface of the n-type diffusion region 214 and extends in the y direction to the backside ground rail 1045. In some implementations, the first backside contact 1050 may be coupled to the backside positive supply rail 1040 through a first backside via (e.g., BVD in FIG. 1E), and the second backside contact 1055 may be coupled to the backside ground rail 1045 through a second backside via (e.g., BVD in FIG. 1E).

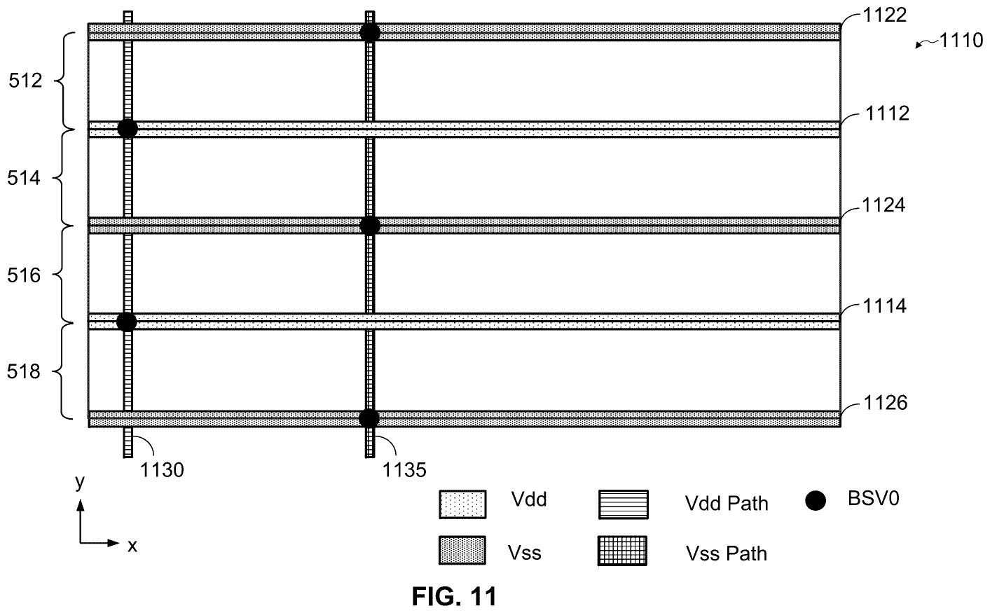

FIG. 11 shows an exemplary layout 1110 for backside power routing in backside metal layers BM0 and BMI for the rows 512, 514, 516, and 518 according to certain aspects of the present disclosure. In this example, the backside power routing includes backside positive supply rails 1112 and 1114 in backside metal layer BM0, and backside ground rails 1122, 1124, and 1126 in backside metal layer BM0. Each of the backside rails 1112, 1114, 1122, 1124, and 1126 extends in the x direction.

In this example, each of the backside rails 1112, 1114, 1122, 1124, and 1126 lies along the boundaries of two rows, allowing each of the rails 1112, 1114, 1122, 1124, and 1126 to be shared by cells in two rows. However, this arrangement places restrictions on the placement of cells in the rows 512, 514, 516, and 518. For example, the arrangement of the rails 1112, 1114, 1122, 1124, and 1126 prevents the multi-row cell 610 from being placed across the rows 514 and 516, as illustrated in FIG. 7B.

In the example in FIG. 11, the backside power routing also includes a backside positive supply path 1130 in backside metal layer BM1 and a backside ground path 1135 in backside metal layer BM1. The positive supply path 1130 extends in the y direction under the backside positive supply rails 1112 and 1114. Each of backside positive supply rails 1112 and 1114 is coupled to the backside positive supply path 1130 by a respective backside via (BSVO in FIGS. 1D and 1D) disposed between the backside positive supply rail and the backside positive supply path 1130. The backside vias are depicted as black circles in FIG. 11. The backside positive supply path 1130 distributes the supply voltage Vdd to the backside positive supply rails 1112 and 1114.

The ground path 1135 extends in the y direction under the backside ground rails 1122, 1124, and 1126. Each of backside ground rails 1122, 1124, and 1126 is coupled to the backside ground path 1135 by a respective backside via (BSVO in FIGS. 1D and 1D) disposed between the backside ground rail and the backside ground path 1135. The backside vias are depicted as black circles in FIG. 11.

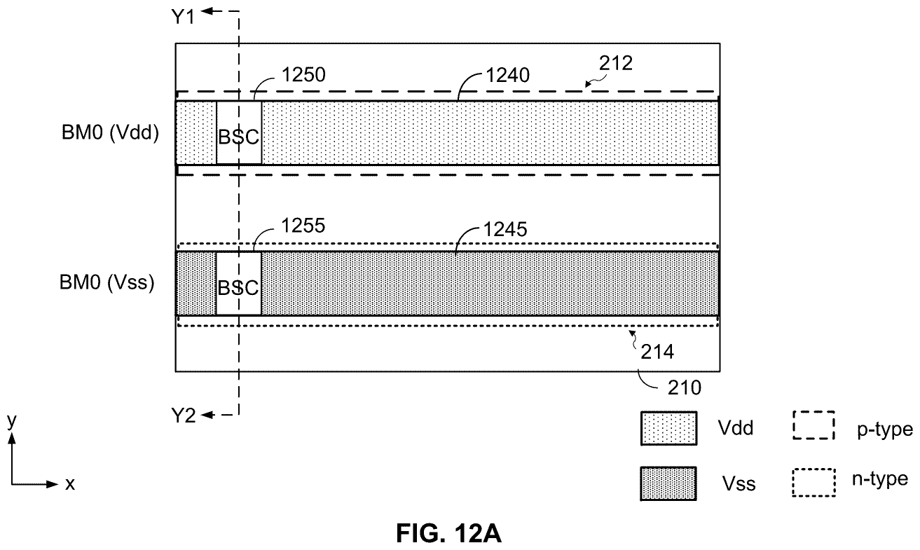

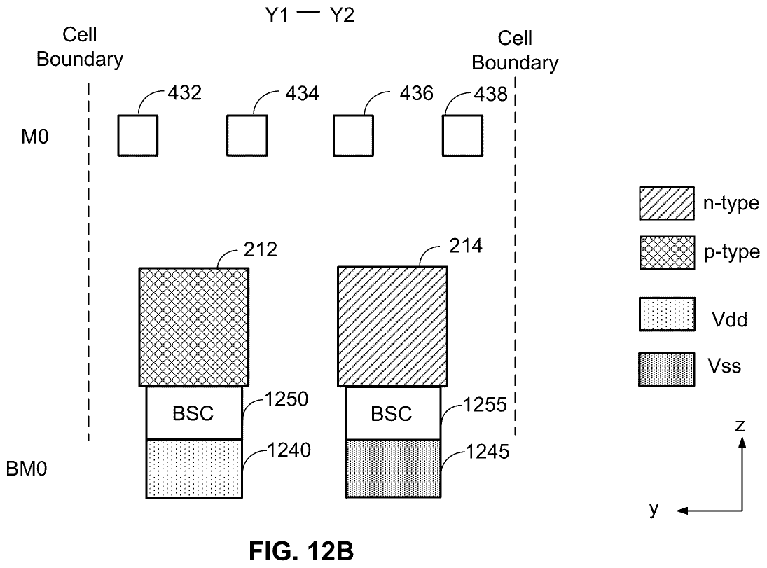

FIG. 12A shows a top view of another example of backside power routing for the cell 210 according to certain aspects. In this example, the backside power routing includes a backside positive supply rail 1240 and a backside ground rail 1245 in backside metal layer BM0. In FIG. 12A, the p-type diffusion region 212 is shown in dashed line, and the n-type diffusion region 214 is shown in dotted line. The gates 222, 224, 226, and 228 and the tracks 432, 434, 436, and 438 are not shown in FIG. 12A. As discussed further below, the exemplary backside power routing shown in FIG. 12A can be used to avoid the cell placement restriction due to the shared rails 1112, 1114, 1122, 1124, and 1126 in FIG. 11.

In this example, most or all of the substrate 108 is removed and the backside positive supply rail 1240 and the backside ground rail 1245 are formed under the cell 210. Since most or all of the substrate 108 is removed, the n-well 310 and the p-well 320 in FIGS. 3A and 3B may be omitted, which eliminates the restrictions on cell placement due to the n-well 310 and the p-well 320.

In this example, the backside positive supply rail 1240 extends in the x direction under the p-type diffusion region 212, and the backside ground rail 1245 extends in the x direction under the n-type diffusion region 214. The backside positive supply rail 1240 receives the supply voltage Vdd from a backside power distribution formed in the backside layers 155 (shown in FIGS. 1D and 1E). In this example, the backside positive supply rail 1240 and the backside ground rail 1245 are internal rails located within the boundary of the cell 210. As discussed further below, the internal rails facilitate power islanding, which provide greater cell placement flexibility.

FIG. 12B shows a cross-sectional view of the tracks 432, 434, 436, and 438, the diffusion regions 212 and 214, the backside positive supply rail 1240, and the backside ground rail 1245 taken along line Y1-Y2 in FIGS. 9 and 12A. In this example, the p-type diffusion region 212 is coupled to the backside positive supply rail 1240 through a first backside contact 1250 disposed between the p-type diffusion region 212 and the backside positive supply rail 1240. The n-type diffusion region 214 is coupled to the backside ground rail 1245 through a second backside contact 1255 disposed between the n-type diffusion region 214 and the backside ground rail 1245. In some implementations, the first backside contact 1250 may be coupled to the backside positive supply rail 1240 through a first backside via (e.g., BVD in FIG. 1E), and the second backside contact 1255 may be coupled to the backside ground rail 1245 through a second backside via (e.g., BVD in FIG. 1E). It is to be appreciated that the backside positive rail 1240 may be off centered with the p-type diffusion region 212 in the y direction and the backside ground rail 1245 may be off centered with the n-type diffusion region 214 in the y direction in some implementations. It is also to be appreciated that the rails 1240 and 1245 may be wider in the y direction than shown in FIGS. 12A and 12B in some implementations.

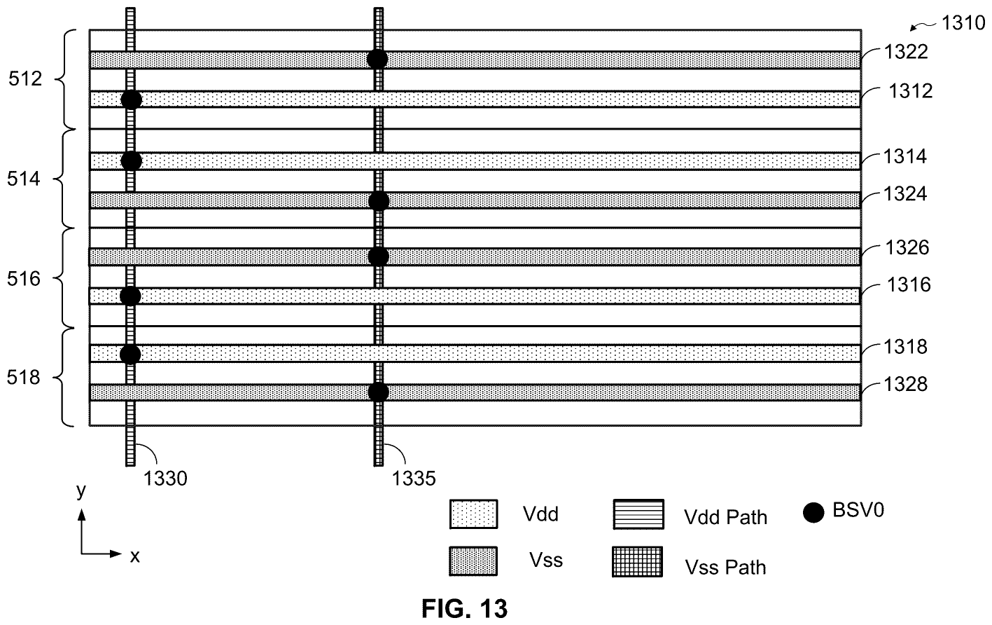

FIG. 13 shows an exemplary layout 1310 for backside power routing in backside metal layers BM0 and BMI for the rows 512, 514, 516, and 518 according to certain aspects of the present disclosure. In this example, the backside power routing includes backside positive supply rails 1312, 1314, 1316, and 1318 in backside metal layer BM0, and backside ground rails 1322, 1324, 1326, and 1328 in backside metal layer BM0. Each of the backside rails 1312, 1312, 1314, 1316, 1318, 1322, 1324, 1326, and 1328 extends in the x direction.

In this example, a respective pair of the backside rails 1312, 1312, 1314, 1316, 1318, 1322, 1324, 1326, and 1328 is located within each of the rows 512, 514, 516, and 518. More particularly, the backside positive supply rail 1312 and the backside ground rail 1322 are located within the row 512, the backside positive supply rail 1314 and the backside ground rail 1324 are located within the row 514, the backside positive supply rail 1316 and the backside ground rail 1326 are located within the row 516, and the backside positive supply rail 1318 and the backside ground rail 1328 are located within the row 518. Thus, in this example, the backside power routing includes two internal rails (i.e., dual internal rails) for each of the rows 512, 514, 516, and 518. As discussed further below, the dual internal rails for each of the rows 512, 514, 516, and 518 facilitate local backside power islanding, which allows flexible placement of cells.

In the example in FIG. 13, the backside power routing also includes a backside positive supply path 1330 in backside metal layer BMI and a backside ground path 1335 in backside metal layer BM1. The backside positive supply path 1330 extends in the y direction under the backside positive supply rails 1312, 1314, 1316, and 1318. Each of backside positive supply rails 1312, 1314, 1316, and 1318 is coupled to the backside positive supply path 1330 by a respective backside via (BSV0 in FIGS. 1D and 1D) disposed between the backside positive supply rail and the backside positive supply path 1330. The backside vias are depicted as black circles in FIG. 13. The backside positive supply path 1330 distributes the supply voltage Vdd to the backside positive supply rails 1312, 1314, 1316, and 1318.

The backside ground path 1335 extends in the y direction under the backside ground rails 1322, 1324, 1326, and 1328. Each of backside ground rails 1322, 1324, 1326, and 1328 is coupled to the backside ground path 1335 by a respective backside via (BSV0 in FIGS. 1D and 1D) disposed between the backside ground rail and the backside ground path 1335. The backside vias are depicted as black circles in FIG. 13. The backside ground path 1335 couples the backside ground rails 1322, 1324, 1326, and 1328 to a ground.

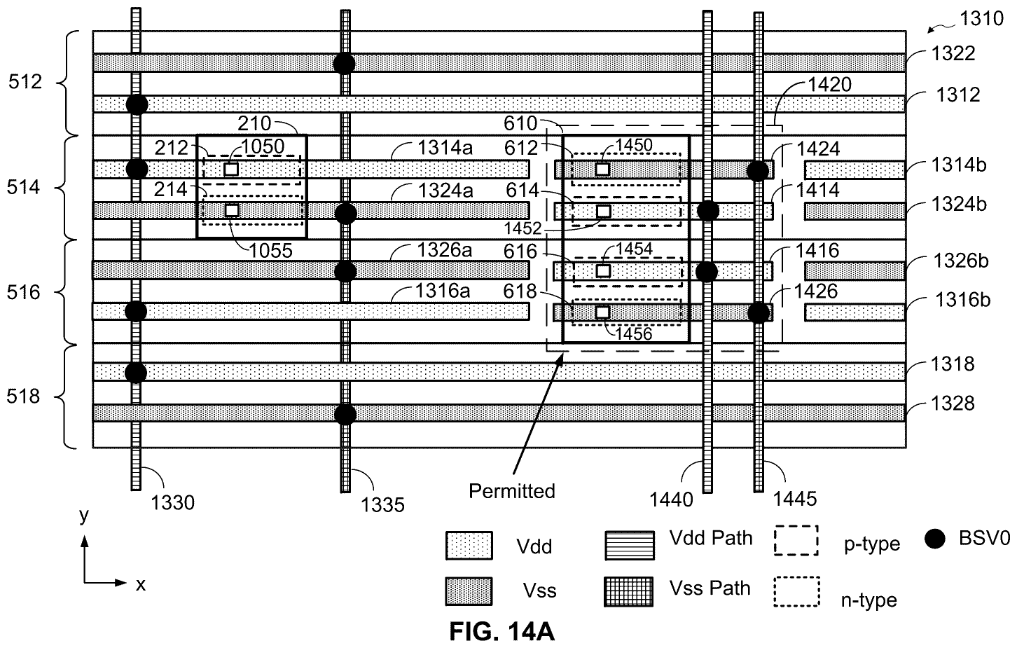

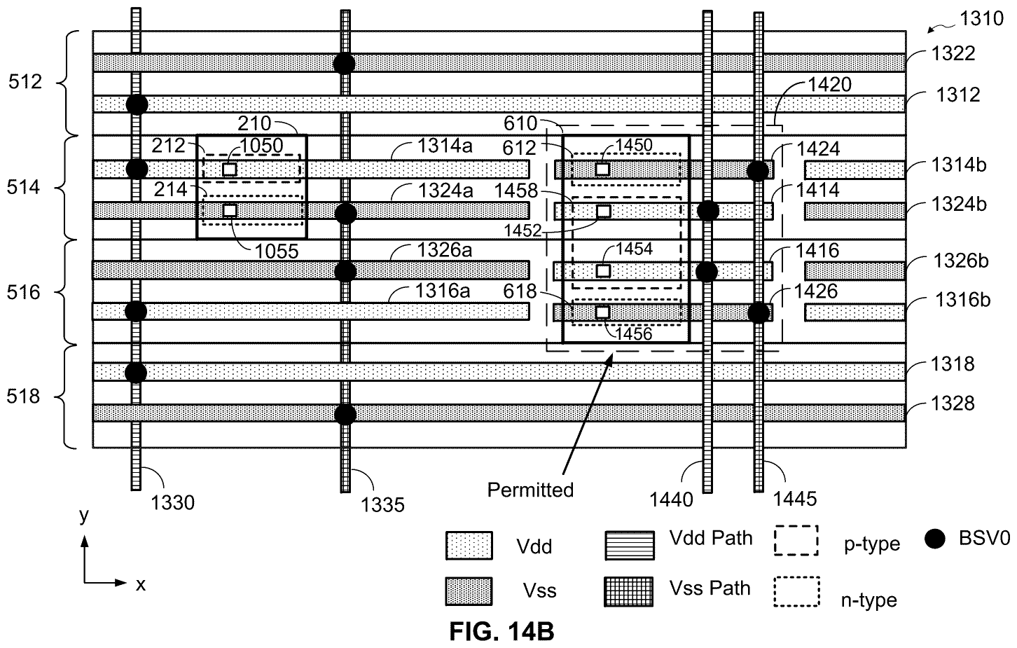

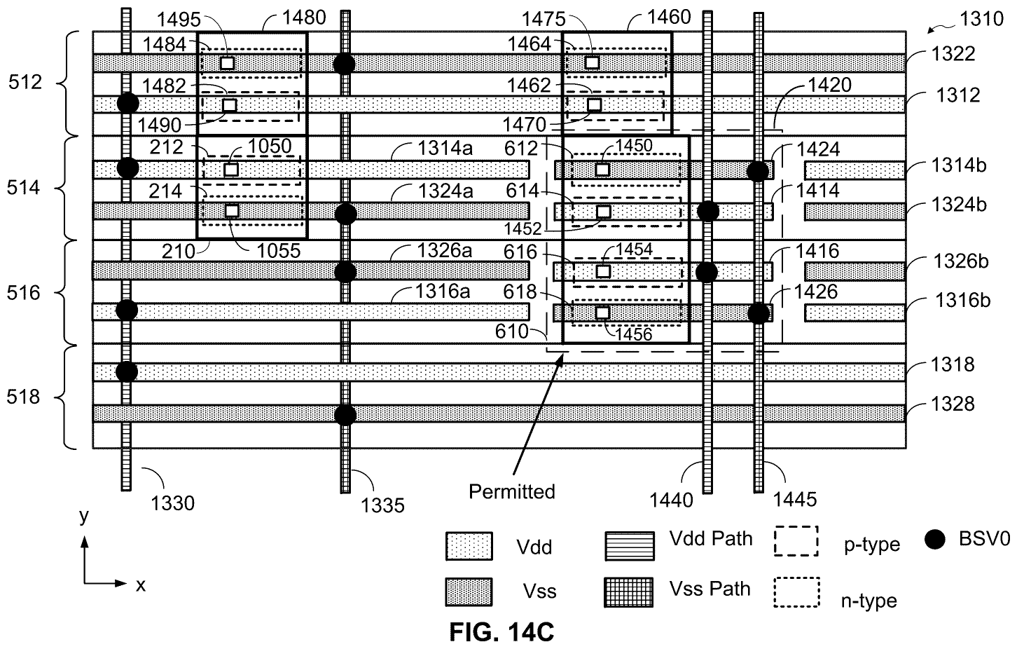

Examples of local backside power islanding using the dual internal rail layout illustrated in FIGS. 12A. 12B, and FIG. 13 will now be discussed with references to FIGS. 14A. 14B, 14C, and 15.

FIG. 14A shows an example in which the backside power routing layout 1310 includes a backside power inland 1420. Within the backside power island 1420, the orientation (i.e., placement) of the positive supply rail and the ground rail in a row can be changed (e.g., flipped in the y direction) to facilitate placement of a cell within the backside power island 1420. Since the backside power routing layout 1310 uses a dual internal routing layout, the change in the orientation of the positive supply rail and the ground rail within the backside power island 1420 does not affect the power routing for a row adjacent to the backside power island 1420.

In the example in FIG. 14A, the backside power island 1420 extends across the rows 514 and 516 in the y direction. Outside of the backside power island 1420, the positive supply rails 1314a and 1314b in the row 514 are located above the respective ground rails 1324a and 1324b in the row 514 in the y direction. Within the backside power island 1420, the ground rail 1424 in the row 514 is located above the positive supply rail 1414 in the row 514 in the y direction. Thus, the orientation (i.e., placement) of the positive supply rail 1414 and the ground rail 1424 within the backside power island 1420 is flipped in the y direction with respect to the orientation of the positive supply rail 1314a and the ground rail 1324a outside of the power island 1420 and the orientation of the positive supply rail 1314b and the ground rail 1324b outside of the power inland 1420.

In this example, the positive supply rail 1414 within the backside power island 1420 is aligned with the ground rails 1324a and 1324b in the y direction. The positive supply rail 1414 is separated from the ground rails 1324a and 1324b in the x direction by small gaps that electrically isolate the positive supply rail 1414 from the ground rails 1324a and 1324b. During processing, the positive supply rail 1414 and the ground rails 1324a and 1324b may initially be part of a long contiguous rail extending in the x direction in backside metal layer BM0. The long contiguous rail may then be cut at the boundaries of the power island 1420 to separate the positive supply rail 1414 from the ground rails 1324a and 1324b.

In this example, the ground rail 1424 within the backside power island 1420 is aligned with the positive supply rails 1314a and 1314b in the y direction. The ground rail 1424 is separated from the positive supply rails 1314a and 1314b in the x direction by small gaps that electrically isolate the ground rail 1424 from the positive supply rails 1314a and 1314b. During processing, the ground rail 1424 and the positive supply rails 1314a and 1314b may initially be part of a long contiguous rail extending in the x direction in backside metal layer BM0. The long contiguous rail may then be cut at the boundaries of the power island 1420 to separate the ground rail 1424 from the positive supply rails 1314a and 1314b.

Also, in this example, outside of the backside power island 1420, the positive supply rails 1316a and 1316b in the row 516 are located below the respective ground rails 1326a and 1326b in the row 516 in the y direction. Within the backside power island 1420, the positive supply rail 1416 in the row 516 is located above the ground rail 1426 in the row 516 in the y direction. Thus, the orientation (i.e., placement) of the positive supply rail 1416 and the ground rail 1426 within the backside power island 1420 is flipped in the y direction with respect to the orientation of the positive supply rail 1316a and the ground rail 1326a outside of the power island 1420 and the orientation of the positive supply rail 1316b and the ground rail 1326b outside of the power island 1420.

In this example, the backside power routing layout 1310 also includes a second positive supply path 1440 and a second ground path 1445 in metal layer BM1. The second positive supply path 1440 extends under the positive supply rails 1414 and 1416 in the y direction and is coupled to the positive supply rails 1414 and 1416 by respective vias (shown as black circles). The second positive supply path 1440 distributes the supply voltage Vdd to the positive supply rails 1414 and 1416 with the backside power island 1420. The second ground path 1445 extends under the ground rails 1424 and 1426 in the y direction and is coupled to the ground rails 1424 and 1426 by respective vias (shown as block circles). In this example, the second positive supply path 1440 and the second ground rail 1455 allow the positive supply rails 1414 and 1416 and the ground rails 1424 and 1426 within the backside power island 1420 to be orientated independently of the orientations of the positive supply rails and the ground rails outside of the backside power island 1420. It is to be appreciated that the layout 1310 may include one or more additional positive supply paths in metal layer BMI and one or more addition ground paths in metal layer BMI not shown in FIG. 14A.

In this example, the backside power island 1420 allows the multi-row cell 610 to be placed across the rows 514 and 516, as shown in FIG. 14A. This is because, within the backside power island 1420, the positive supply rails 1414 and 1416 extends under the p-type diffusion regions 614 and 616 in the cell 610, and the ground rails 1424 and 1426 extend under the n-type diffusion regions 612 and 618 in the cell 610. In contrast, the cell 610 cannot be placed across rows 514 and 516 in the example shown in FIG. 7B.

In the example in FIG. 14A, the layout 1310 includes a first backside contact 1450 coupling the n-type diffusion region 612 to the backside ground rail 1424, a second backside contact 1452 coupling the p-type diffusion region 614 to the backside positive supply rail 1414, a third backside contact 1454 coupling the p-type diffusion region 616 to the backside positive supply rail 1416, and a fourth backside contact 1456 coupling the n-type diffusion region 618 to the backside ground rail 1426. Each of the backside contacts 1450, 1452, 1454, and 1456 may be in the backside contact layer (e.g., BSC shown in FIGS. 1D, 1E, and 12B). Although the backside contacts 1450, 1452, 1454, and 1456 are aligned in the x direction in the example shown in FIG. 14A, it is to be appreciated that this need not be the case. It is also to be appreciated that the layout 1310 may include additional backside contacts.

FIG. 14A also shows an example in which the cell 210 is placed in the row 514. In this example, the positive supply rail 1314a extends under the p-type diffusion region 212 in the cell 210, and the ground rail 1324a extends under the n-type diffusion region 214 in the cell 210. The p-type diffusion region 212 may be coupled to the positive supply rail 1314a by the first backside contact 1050 disposed between the p-type diffusion region 212 and the positive supply rail 1314a. The n-type diffusion region 214 may be coupled to the ground rail 1324a by the second backside contact 1055 disposed between the n-type diffusion region 214 and the ground rail 1324a. In this example, the positive supply rail 1314a and the ground rail 1324a may correspond to the backside positive supply rail 1040 and the backside ground rail 1045, respectively, shown in FIGS. 10A and 10B. The backside contacts 1050, 1055, 1450, 1452, 1454, and 1456 may be in the same backside contact layer (e.g., BSC in FIGS. 1D and 1E). In the example in FIG. 14A, the p-type diffusion region 212 in the cell 210 is aligned with the n-type diffusion region 612 in the cell 610 in the y direction, and the n-type diffusion region 214 in the cell 210 is aligned with the p-type diffusion region 614 in the cell 610 in the y direction.

FIG. 14B shows an example in which the p-type diffusion regions 614 and 616 shown in FIG. 14A are merged into a wide p-type diffusion region 1458. The wide p-type diffusion region 1458 may be coupled to the backside positive supply rails 1414 and 1416 by the backside contacts 1452 and 1454, as shown in the example in FIG. 14B. However, it is to be appreciated that the present disclosure is not limited to this example.

FIG. 14C shows an example of a cell 1460 in row 512, in which the cell 1460 is adjacent to the cell 610 (i.e., there is no intervening cell between cells 1460 and 610). In this example, the cell 1460 includes a p-type diffusion region 1462 and an n-type diffusion region 1464, in which the positive supply rail 1312 extends under the p-type diffusion region 1462 and the ground rail 1322 extends under the n-type diffusion region 1464. Each of the diffusion regions 1462 and 1464 may include one or more channels (e.g., one or more instances of the one or more channels 170) and one or more epi layers (e.g., one or more instances of the epi layers 114 and 116). The p-type diffusion region 1462 may be coupled to the positive supply rail 1312 by a first backside contact 1470 disposed between the p-type diffusion region 1462 and the positive supply rail 1312. The n-type diffusion region 1464 may be coupled to the ground rail 1322 by a second backside contact 1475 disposed between the n-type diffusion region 1464 and the ground rail 1322. In this example, the dual internal rails for each of the rows 512 and 514 allows the cell 1460 to be placed adjacent to the cell 610.

FIG. 14C also shows an example of another cell 1480 in row 512, in which the cell 1480 is adjacent to the cell 210 (i.e., there is no intervening cell between cells 1460 and 210). In this example, the cell 1480 includes a p-type diffusion region 1482 and an n-type diffusion region 1484, in which the positive supply rail 1312 extends under the p-type diffusion region 1482 and the ground rail 1322 extends under the n-type diffusion region 1484. Each of the diffusion regions 1482 and 1484 may include one or more channels (e.g., one or more instances of the one or more channels 170) and one or more epi layers (e.g., one or more instances of the epi layers 114 and 116). The p-type diffusion region 1482 may be coupled to the positive supply rail 1312 by a first backside contact 1490 disposed between the p-type diffusion region 1482 and the positive supply rail 1312. The n-type diffusion region 1484 may be coupled to the ground rail 1322 by a second backside contact 1495 disposed between the n-type diffusion region 1484 and the ground rail 1322.

It is to be appreciated that the rails 1312, 1322, 1314a, 1314b, 1324a, 1324b, 1326a, 1326b, 1316a, 1316b, 1318, 1326, 1424, 1414, 1416, and 1426 may be wider in the y direction than shown in FIGS. 14A to 14C in some implementations.

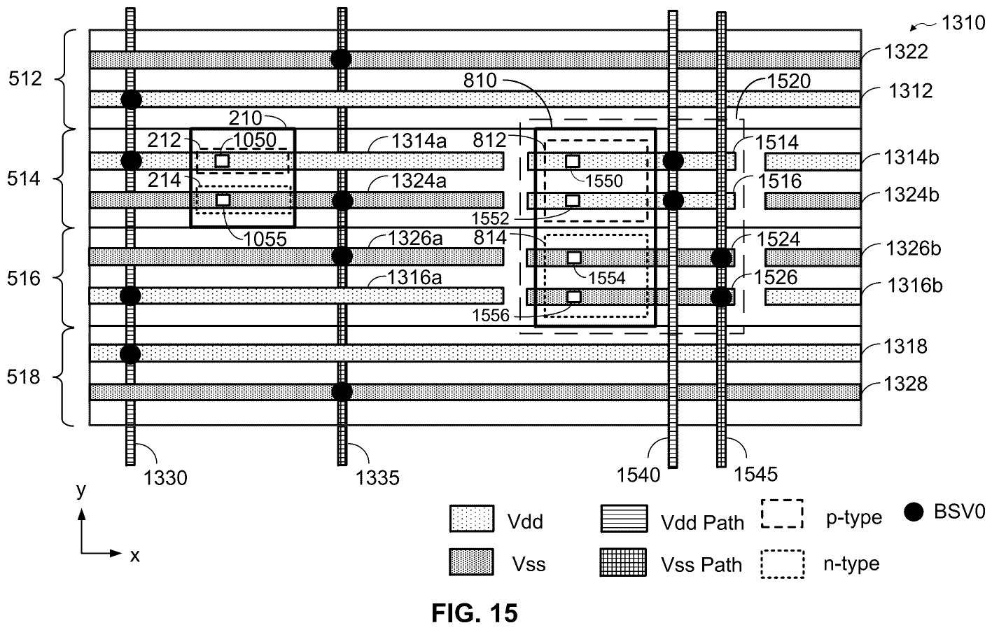

FIG. 15 shows another example of a backside power inland 1520 according to certain aspects. In this example, the backside power island 1520 allows two positive supply rails or two ground rails to be placed in the same row to facilitate area efficient placement of an HP cell with wide diffusion regions (e.g., the HP cell 810).

In the example in FIG. 15, the backside power island 1520 extends across the rows 514 and 516 in the y direction. The backside power island 1520 includes a first positive supply rail 1514 and a second positive supply rail 1516 in the row 514. The first positive supply rail 1514 is aligned with the positive supply rails 1314a and 1314b in the row 514 in the y direction, and the second positive supply rail 1516 is aligned with the ground rails 13154a and 1324b in the row 514. The backside power island 1520 also includes a first ground rail 1524 and a second ground rail 1526 in the row 516. The first ground rail 1524 is aligned with the ground rails 1326a and 1326b in the row 516 in the y direction, and the second ground rail 1526 is aligned with the positive supply rails 1316a and 1316b in the row 516 in the y direction.

In this example, the backside power routing layout 1310 also includes a second positive supply path 1540 and a second ground path 1545 in metal layer BM1. The second positive supply path 1540 extends under the positive supply rails 1514 and 1516 in the y direction and is coupled to the positive supply rails 1514 and 1516 by respective vias (shown as black circles). The second positive supply path 1540 distributes the supply voltage Vdd to the positive supply rails 1514 and 1516 with the backside power island 1520. The second ground path 1545 extends under the ground rails 1524 and 1526 in the y direction and is coupled to the ground rails 1524 and 1526 by respective vias (shown as block circles). In this example, the second positive supply path 1540 and the second ground path 1545 allow the positive supply rails 1514 and 1516 to be in the same row (i.e., the row 514) and the ground rails 1524 and 1526 to be in the same row (i.e., the row 516) without affecting the power routing outside of the backside power island 1520.

In this example, the backside power island 1520 allows the HP cell 810 to be placed across the rows 514 and 516, which improves area efficiency compared with the example illustrated in FIG. 8. This is because the first and second positive supply rails 1514 and 1516 in the row 514 allow the wide p-type diffusion region 815 of the cell 810 to be placed in the row 514, and the first and second ground rails 1524 and 1526 in the row 516 allow the wide n-type diffusion region 814 of the cell 810 to be placed in the row 516. Thus, in this example, the HP cell 810 extends across two rows (i.e., rows 514 and 516). In contrast, in the example in FIG. 8, the HP cell 810 extends across the row 514 and extends partially across the rows 515 and 516. As a result, an area extending across three rows is needed for placement of the cell 810, which leads to the wasted arca indicated in FIG. 8.

In the example in FIG. 15, the layout 1310 includes a first backside contact 1550 coupling the wide p-type diffusion region 812 to the backside positive supply rail 1514, a second backside contact 1552 coupling the wide p-type diffusion region 812 to the backside positive supply rail 1516, a third backside contact 1554 coupling the wide n-type diffusion region 814 to the backside ground rail 1524, and a fourth backside contact 1556 coupling the wide n-type diffusion region 814 to the backside ground rail 1526. Each of the backside contacts 1550, 1552, 1554, and 1556 may be in the backside contact layer (e.g., BSC shown in FIGS. 1D, 1E, and 12B). Although the backside contacts 1550, 1552, 1554, and 1556 are aligned in the x direction in the example shown in FIG. 15, it is to be appreciated that this need not be the case. It is also to be appreciated that the layout 1310 may include additional backside contacts. The backside contacts 1050, 1055, 1550, 1552, 1554, and 1556 may be in the same backside contact layer (e.g., BSC in FIGS. 1D and 1E).

FIG. 15 also shows an example in which the cell 210 is placed in the row 514. In this example, the positive supply rail 1314a extends under the p-type diffusion region 212 in the cell 210, and the ground rail 1324a extends under the n-type diffusion region 214 in the cell 210.

Implementation examples are described in the following numbered clauses:
1. A chip, comprising:
   a first positive supply rail extending in a first direction;
   a first ground rail extending in the first direction;
   a second positive supply rail extending in the first direction, wherein the second positive supply rail is aligned with the first ground rail in a second direction perpendicular to the first direction; and
   a second ground rail extending in the first direction, wherein the second ground rail is aligned with the first positive supply rail in the second direction.
2. The chip of clause 1, further comprising:
   a first p-type diffusion region extending in the first direction, wherein the first positive supply rail extends under the first p-type diffusion region; and
   a first n-type diffusion region extending in the first direction, wherein the first ground rail extends under the first n-type diffusion region.
3. The chip of clause 2, further comprising:
   a first backside contact coupled between the first p-type diffusion region and the first positive supply rail; and
   a second backside contact coupled between the first n-type diffusion region and the first ground rail.
4. The chip of clause 2 or 3, further comprising:
   a second p-type diffusion region extending in the first direction, wherein the second positive supply rail extends under the second p-type diffusion region; and
   a second n-type diffusion region extending in the first direction, wherein the second ground rail extends under the second n-type diffusion region.
5. The chip of clause 4, wherein the first p-type diffusion region is aligned with the second n-type diffusion region in the second direction, and the first n-type diffusion region is aligned with the second p-type diffusion region in the second direction.
6. The chip of clause 4 or 5, further comprising:
   a first backside contact coupled between the first p-type diffusion region and the first positive supply rail;
   a second backside contact coupled between the first n-type diffusion region and the first ground rail;
a third backside contact coupled between the second p-type diffusion region and the second positive supply rail; and
   a fourth backside contact coupled between the second n-type diffusion region and the second ground rail.
7. The chip of any one of clauses 1 to 6, further comprising:
   a first positive supply path extending in the second direction under the first positive supply rail, wherein the first positive supply path is coupled to the first positive supply rail; and
   a second positive supply path extending in the second direction under the second positive supply rail, wherein the second positive supply path is coupled to the second positive supply rail, and the second positive supply path is spaced apart from the first positive supply path in the first direction.
8. The chip of clause 7, further comprising:
   a first ground path extending in the second direction under the first ground rail, wherein the first ground path is coupled to the first ground rail; and
   a second ground path extending in the second direction under the second ground rail, wherein the second ground path is coupled to the second ground rail, and the second ground path is spaced apart from the first ground path in the first direction.
9. The chip of clause 1, further comprising:
   a third positive supply rail extending in the first direction; and
   a third ground rail extending in the first direction, wherein the third ground rail is aligned with the third positive supply rail in the second direction.
10. The chip of clause 9, further comprising:
   a first p-type diffusion region extending in the first direction, wherein the first positive supply rail extends under the first p-type diffusion region, and the third positive supply rail extends under the first p-type diffusion region; and
   a first n-type diffusion region extending in the first direction, wherein the first ground rail extends under the first n-type diffusion region.
11. The chip of clause 10, further comprising:
   a second p-type diffusion region extending in the first direction, wherein the second positive supply rail extends under the second p-type diffusion region, and the first p-type diffusion region is wider than the second p-type diffusion region in the second direction; and
   a second n-type diffusion region extending in the first direction, wherein the second ground rail extends under the second n-type diffusion region.
12. A chip, comprising:
   a first positive supply rail extending in a first direction;
   a ground rail extending in the first direction;
   a second positive supply rail extending in the first direction, wherein the second positive supply rail is aligned with the first positive supply rail in a second direction perpendicular to the first direction; and
   a third positive supply rail extending in the first direction, wherein the third positive supply rail is aligned with the ground rail in the second direction.
13. The chip of clause 12, further comprising:
   a first p-type diffusion region extending in the first direction, wherein the first positive supply rail extends under the first p-type diffusion region; and
   a first n-type diffusion region extending in the first direction, wherein the ground rail extends under the first n-type diffusion region.
14. The chip of clause 13, further comprising a second p-type diffusion region extending in the first direction, wherein the second positive supply rail extends under the second p-type diffusion region, and the third positive supply rail extends under the second p-type diffusion region.
15. The chip of clause 14, wherein the second p-type diffusion region is wider than the first p-type diffusion region in the second direction.
16. The chip of clause 14 or 15, further comprising:
   a first backside contact coupled between the first p-type diffusion region and the first positive supply rail;
   a second backside contact coupled between the first n-type diffusion region and the ground rail; and
a third backside contact coupled between the second p-type diffusion region and the second positive supply rail.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first positive supply rail extending in a first direction;
a first ground rail extending in the first direction;
a second positive supply rail extending in the first direction, wherein the second positive supply rail is aligned with the first ground rail in a second direction perpendicular to the first direction; and
a second ground rail extending in the first direction, wherein the second ground rail is aligned with the first positive supply rail in the second direction.

2. The chip of claim 1, further comprising:
a first p-type diffusion region extending in the first direction, wherein the first positive supply rail extends under the first p-type diffusion region; and
a first n-type diffusion region extending in the first direction, wherein the first ground rail extends under the first n-type diffusion region.

3. The chip of claim 2, further comprising:
a first backside contact coupled between the first p-type diffusion region and the first positive supply rail; and
a second backside contact coupled between the first n-type diffusion region and the first ground rail.

4. The chip of claim 2, further comprising:
a second p-type diffusion region extending in the first direction, wherein the second positive supply rail extends under the second p-type diffusion region; and
a second n-type diffusion region extending in the first direction, wherein the second ground rail extends under the second n-type diffusion region.

5. The chip of claim 4, wherein the first p-type diffusion region is aligned with the second n-type diffusion region in the second direction, and the first n-type diffusion region is aligned with the second p-type diffusion region in the second direction.

6. The chip of claim 4, further comprising:
a first backside contact coupled between the first p-type diffusion region and the first positive supply rail;
a second backside contact coupled between the first n-type diffusion region and the first ground rail;
a third backside contact coupled between the second p-type diffusion region and the second positive supply rail; and
a fourth backside contact coupled between the second n-type diffusion region and the second ground rail.

7. The chip of claim 1, further comprising:
a first positive supply path extending in the second direction under the first positive supply rail, wherein the first positive supply path is coupled to the first positive supply rail; and
a second positive supply path extending in the second direction under the second positive supply rail, wherein the second positive supply path is coupled to the second positive supply rail, and the second positive supply path is spaced apart from the first positive supply path in the first direction.

8. The chip of claim 7, further comprising:
a first ground path extending in the second direction under the first ground rail, wherein the first ground path is coupled to the first ground rail; and
a second ground path extending in the second direction under the second ground rail, wherein the second ground path is coupled to the second ground rail, and the second ground path is spaced apart from the first ground path in the first direction.

9. The chip of claim 1, further comprising:
a third positive supply rail extending in the first direction; and
a third ground rail extending in the first direction, wherein the third ground rail is aligned with the third positive supply rail in the second direction.

10. The chip of claim 9, further comprising:
a first p-type diffusion region extending in the first direction, wherein the first positive supply rail extends under the first p-type diffusion region, and the third positive supply rail extends under the first p-type diffusion region; and
a first n-type diffusion region extending in the first direction, wherein the first ground rail extends under the first n-type diffusion region.

11. The chip of claim 10, further comprising:
a second p-type diffusion region extending in the first direction, wherein the second positive supply rail extends under the second p-type diffusion region, and the first p-type diffusion region is wider than the second p-type diffusion region in the second direction; and
a second n-type diffusion region extending in the first direction, wherein the second ground rail extends under the second n-type diffusion region.

12. A chip, comprising:
a first positive supply rail extending in a first direction;
a ground rail extending in the first direction;
a second positive supply rail extending in the first direction, wherein the second positive supply rail is aligned with the first positive supply rail in a second direction perpendicular to the first direction; and
a third positive supply rail extending in the first direction, wherein the third positive supply rail is aligned with the ground rail in the second direction.

13. The chip of claim 12, further comprising:
a first p-type diffusion region extending in the first direction, wherein the first positive supply rail extends under the first p-type diffusion region; and
a first n-type diffusion region extending in the first direction, wherein the ground rail extends under the first n-type diffusion region.

14. The chip of claim 13, further comprising a second p-type diffusion region extending in the first direction, wherein the second positive supply rail extends under the second p-type diffusion region, and the third positive supply rail extends under the second p-type diffusion region.

15. The chip of claim 14, wherein the second p-type diffusion region is wider than the first p-type diffusion region in the second direction.

16. The chip of claim 14, further comprising:
a first backside contact coupled between the first p-type diffusion region and the first positive supply rail;
a second backside contact coupled between the first n-type diffusion region and the ground rail; and
a third backside contact coupled between the second p-type diffusion region and the second positive supply rail.
